(19) United States
(12) Patent Application Publication
(10) Pub. No.: US 2023/0039535 A1
(43) Pub. Date: Feb. 9, 2023

(54) COMPOSITION, COMPOSITION PRECURSOR SOLUTION, PRODUCTION METHOD FOR COMPOSITION, SUBSTRATE WITH MULTILAYER FILM, AND PRODUCTION METHOD FOR PATTERNED SUBSTRATE

(71) Applicant: CENTRAL GLASS COMPANY, LIMITED, Ube-shi (JP)

(72) Inventors: Yuri OIKAWA, Saitama (JP); Takashi MASUBUCHI, Saitama (JP); Kazuhiro YAMANAKA, Yamaguchi (JP)

(21) Appl. No.: 17/944,817

(22) Filed: Sep. 14, 2022

Related U.S. Application Data
(63) Continuation of application No. PCT/JP2021/005907, filed on Feb. 17, 2021.

(30) Foreign Application Priority Data
Mar. 16, 2020 (JP) 2020-045837

(51) Int. Cl. G03F 7/11; C08G 77/24; C09D 183/08

(52) U.S. Cl. CPC G03F 7/11; C08G 77/24; C09D 183/08; C08G 77/70

(57) ABSTRACT

A composition including a polysiloxane compound (A) containing a structural unit represented by formula (1) and a structural unit represented by formula (2), wherein a siloxane structural unit ratio represented by Q unit/(Q unit+T unit) in all Si structural units is 0.60 or more and less than 1.00, and the solvent (B).

[(R¹)_{b}(R²)ₘ(OR³)ₗSiO_{n/2}] (1)

[In the formula, R¹ is a group represented by following formula.]

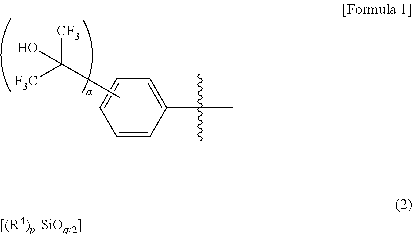

[(R⁴)ₚSiO_{q/2}] (2)

### CROSS-REFERENCE TO RELATED APPLICATIONS

This application is a Continuation of International Patent Application No. PCT/JP2021/5907, filed on Feb. 17, 2021, which claims the benefit of priority to Japanese Patent Application No. 2020-045837, filed on Mar. 16, 2020, the entire contents of which are incorporated herein by reference.

### FIELD

The present disclosure relates to a composition used to form an under layer film of a photoresist.

### BACKGROUND

High integration of LSI (Large Scale Integration) and miniaturization of patterns are advancing. The high integration of the LSI and the miniaturization of patterns have been advanced by shortening the wavelength of the light source in lithography and by development of the resist corresponding to it. Usually, in LSI manufacturing, a patterning substrate is manufactured by dry etching a substrate using a chlorine-based gas or a fluorine-based gas through a resist pattern formed by exposure and development on the substrate in accordance with lithography, and transferring the pattern. In this case, a resin having a chemical structure which has an etching resistance against these gases is used as the resist.

In such a resist, there is a positive resist in which an exposed portion is solubilized by irradiation with a high energy ray, and a negative resist in which an exposed portion is insolubilized, and any one of them is used. In this case, as the high energy ray, g-ray (wavelength: 463 nm) and i-ray (wavelength: 365 nm) emitted by a high-pressure mercury lamp, ultraviolet ray having a wavelength of 248 nm oscillated by a KrF excimer laser or a wavelength of 193 nm oscillated by an ArF excimer laser, or an extreme ultraviolet ray (hereinafter, sometimes referred to as EUV), or the like is used.

In such a resist, a multilayer resist method is known in order to improve the pattern collapse at the time of forming a resist pattern and the etching resistance of the resist. Patent Literature 1 (WO2019/167771A1) discloses a silicon-containing layer forming composition containing a polysiloxane compound (A) containing a structural unit represented by formula (A) and a solvent (B) as a silicon-containing layer forming composition for forming a silicon-containing layer having an anti-reflection function at the time of exposure in a multilayer resist method and having a high etching rate for a plasma of a fluorine-based gas and a low etching rate for a plasma of an oxygen-based gas at the time of dry etching.

[(R^{a})ₚR^{b}_{w}SiO_{x/2}] (A)

[In the formula, R^{a} is a group represented by the following formula.

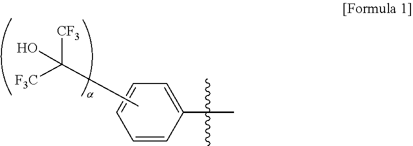

(α is an integer of 1 to 5. The wavy line indicates that the intersecting line segment is a bond.)
R^{b} is independently a hydrogen atom, an alkyl group having 1 or more and 3 or less carbon atoms, a phenyl group, a hydroxy group, an alkoxy group having 1 or more and 3 or less carbon atoms, or a fluoroalkyl group having 1 or more and 3 or less carbon atoms, β is an integer of 1 to 3, w is an integer of 0 to 2, x is an integer of 1 to 3, and β+w+x=4.]

Further, it is disclosed that the above polysiloxane compound (A) may contain a structural unit represented by formula (B).

[Si(R^{d})_{y}O_{z/2}] (B)

[In the formula, R^{d} is independently a hydrogen atom, an alkyl group having 1 or more and 3 or less carbon atoms, a phenyl group, an alkoxy group having 1 or more and 3 or less carbon atoms, or a fluoroalkyl group having 1 or more and 3 or less carbon atoms, y is an integer of 0 to 3, and z is an integer of 1 to 4, and y+z=4.]

In addition, in Example 4 of Patent Literature 1, 3-(2-hydroxy-1, 1,1,3,3,3-hexafluoroisopropyl)-triethoxysilylbenzene, which is a raw material of the formula (A), and a silicate 40, which is a silicate oligomer, are reacted with each other in a molar ratio of 1:1 in the presence of water and acetic acid. Thereafter, it is disclosed that a polysiloxane compound of interest was obtained by distilling off water, acetic acid, and by-produced ethanol.

Patent Literature 2 (Japanese laid-open patent publication No. 2018-159789) discloses a silicon-containing film forming composition for a resist process capable of forming a silicon-containing film excellent in solvent resistance and oxygen-based gas etching resistance, wherein a silicon-containing film forming composition for a resist process contains a polysiloxane having a predetermined first structural unit and a solvent. Further, it is disclosed that, when a component forming a Q unit such as tetramethoxysilane or tetraethoxysilane is used as a raw material of the polysiloxane, it is preferable from the viewpoint of improving the dry etching resistance of the silicon-containing film formed from the film forming composition. Note that the Q unit means a Si structural unit in which the 4 bonds of the Si atom are any of a siloxane bond, a silanol group, and a hydrolyzable group.

### SUMMARY

A composition according to one embodiment of the present invention includes a polysiloxane compound (A) containing a structural unit represented by formula (1) and a structural unit represented by formula (2), a siloxane structural unit ratio represented by

Q unit/(Q unit+T unit)

in all Si structural units being 0.60 or more and less than 1.00; and the solvent (B),

[(R¹)_{b}(R²)ₘ(OR³)ₗSiO_{n/2}] (1)

wherein in the formula, R¹ is a group represented by the following formula,

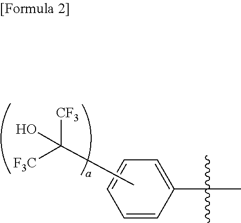

a is a number of 1 to 5, the wavy line indicates that the intersecting line segment is a bond,
wherein R² is each independently a hydrogen atom, an alkyl group having 1 or more and 3 or less carbon atoms, a phenyl group, or a fluoroalkyl group having 1 or more and 3 or less carbon atoms,
wherein R³ is each independently a hydrogen atom, or an alkyl group having 1 or more and 3 or less carbon atoms,
b is a number of 1 to 3, m is a number of 0 to 2, l is a number of 0 or more and less than 3, n is a number of more than 0 and 3 or less, and b+m+l+n=4, and

[(R⁴)ₚ SiO_{q/2}] (2)

wherein in the formula, R⁴ is independently an alkoxy group having 1 or more and 3 or less carbon atoms, a hydroxyl group, or a halogen group, p is a number of 0 or more and less than 4, q is a number of more than 0 and 4 or less, and p+q=4.

a is 1 or 2.

R¹ is one of the following, and

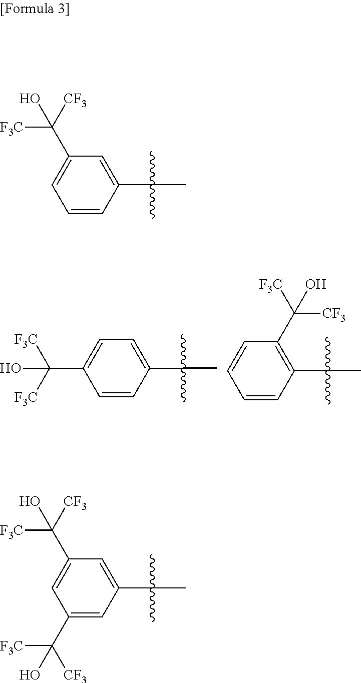

wherein the wavy line indicates that the intersecting line segment is a bond.

b is 1.

n is 0.5 to 3.

The pH at 25° C. is 1 or more and less than 6.

A viscosity at 25° C. is 0.5 mPa·s or more 30 mPa·s or less.

The solvent (B) includes at least one selected from a group consisting of an ester-based solvent, an ether-based solvent, an alcohol-based solvent, a ketone-based solvent, and an amide-based solvent.

An under layer film of a photoresist is formed of the composition.

In the above composition, an etching rate ratio A obtained by dividing an etching rate under a following condition (1) with respect to a film to be etched formed by the composition of an etching rate under a following condition (2) is 50 or more.

[Condition (1)] CF₄ and CHF₃ used as the fluorine-based gas

CF₄ flow rate: 150 sccm

CHF₃ flow rate: 50 sccm

Ar flow rate: 100 sccm

chamber pressure: 10 Pa

applied electric power: 400 W

temperature: 15° C.

[Condition (2)] CO₂ used as the oxygen-based gas

CO₂ flow rate: 300 sccm

Ar flow rate: 100 sccm

N₂ flow rate: 100 sccm

chamber pressure: 2 Pa

applied electric power: 400 W

temperature: 15° C.

In the above composition, an etching rate ratio B obtained by dividing an etching rate under a following condition (1) with respect to a film to be etched formed by the composition of an etching rate under a following condition (3) is 20 or more.

[Condition (1)] CF₄ and CHF₃ used as the fluorine-based gas

CF₄ flow rate: 150 sccm

CHF₃ flow rate: 50 sccm

Ar flow rate: 100 sccm

chamber pressure: 10 Pa

applied electric power: 400 W

temperature: 15° C.

[Condition (3)] O₂ used as the oxygen-based gas

O₂ flow rate: 400 sccm

Ar flow rate: 100 sccm

chamber pressure: 2 Pa

applied electric power: 400 W

temperature: 15° C.

A composition precursor solution according to one embodiment of the present invention includes a composition precursor,

wherein the composition precursor is copolymerizable with at least one selected from a group consisting of chlorosilane, alkoxysilane, and silicate oligomers that give structural units represented by the following formula (2) to provide the composition according to claim 1,

the composition precursor contains the structural unit represented by the following formula (3), and

the composition precursor solution has a pH of 1 or more and 7 or less at 25° C.,

[(R⁴)ₚ SiO_{q/2}] (2)

wherein in the formula, R⁴ is independently an alkoxy group having 1 or more and 3 or less carbon atoms, hydroxyl group, or halogen group, p is a number of 0 or more and less than 4, q is a number of more than 0 and 4 or less, and p+q=4.]

[(R¹)_{b}(R²)ₘ(OR³)ₛ SiO_{t/2}) (3)

wherein in the formula, R¹ is a group represented by the following formula,

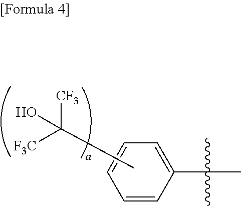

a is a number of 1 to 5, the wavy line indicates that the intersecting line segment is a bond,

wherein R² is each independently a hydrogen atom, an alkyl group having 1 or more and 3 or less carbon atoms, a phenyl group, or a fluoroalkyl group having 1 or more and 3 or less carbon atoms,

wherein R³ is each independently a hydrogen atom, or an alkyl group having 1 or more and 3 or less carbon atoms, b is a number of 1 to 3, m is a number of 0 to 2, s is a number of 0 or more and less than 3, t is a number of more than 0 and 3 or less, and b+m+s+t=4.

A weight average molecular weight of the above composition precursor is 300 to 3000.

a is 1 or 2.

R¹ is one of following, and

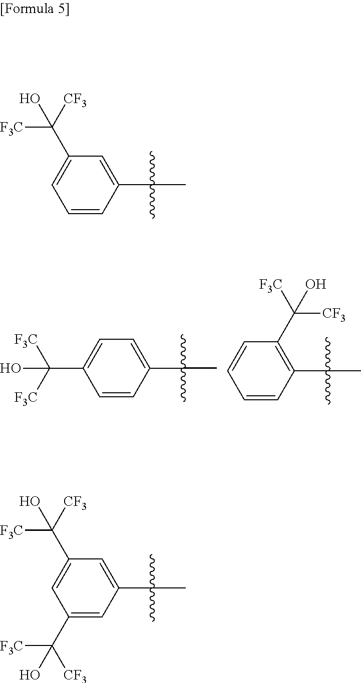

the wavy line indicates that the intersecting line segment is a bond.

b is 1.

A production method for a composition according to one embodiment of the present invention includes

mixing and copolymerizing the composition precursor solution according to claim 12 and at least one selected from a group consisting of chlorosilane, alkoxysilane, and silicate oligomer which give a structural unit represented by the following formula (2),

[(R⁴)ₚ SiO_{q/2}] (2)

wherein in the formula, R⁴ is independently an alkoxy group having 1 or more and 3 or less carbon atoms, a hydroxyl group, or a halogen group, p is a number of 0 or more and less than 4, q is a number of more than 0 and 4 or less, and p+q=4.

The multilayered substrate according to one embodiment of the present invention includes a substrate; an organic layer on the substrate; and an under layer film of a photoresist being a cured product of the composition according to claim 1 on the organic layer, and a resist layer on the under layer film.

A manufacturing method for a patterned substrate comprising:

a first step of obtaining a first pattern by exposing a resist layer with a high energy ray through a photomask to the substrate with the multilayer film according to claim 18 and developing the resist layer with a developer,

a second step of dry etching an under layer film through the first pattern of the resist layer to obtain a second pattern in the under layer film,

a third step of dry etching an organic layer through the second pattern of the under layer film to obtain a third pattern in the organic layer, and

a fourth step of dry etching the substrate through the third pattern of the organic layer to obtain a fourth pattern in the substrate.

In the second step, dry etching of the under layer film is performed with a fluorine-based gas,

in the third step, dry etching of the organic layer is performed with an oxygen-based gas, and

in the fourth step, dry etching of the substrate is performed with a fluorine-based gas or a chlorine-based gas.

The high energy ray is an ultraviolet ray having a wavelength of 1 nm or more and 400 nm or less.

In the above under layer film, the etching rate ratio A obtained by dividing the etching rate under the following condition (1) by the etching rate under the following condition (2) is 50 or more.

[Condition (1)] CF₄ and CHF₃ used as the fluorine-based gas

CF₄ flow rate: 150 sccm

CHF₃ flow rate: 50 sccm

Ar flow rate: 100 sccm

chamber pressure: 10 Pa

applied electric power: 400 W

temperature: 15° C.

[Condition (2)] CO₂ used as the oxygen-based gas

CO₂ flow rate: 300 sccm

Ar flow rate: 100 sccm

N₂ flow rate: 100 sccm

chamber pressure: 2 Pa

applied electric power: 400 W

temperature: 15° C.

In the above under layer film, the etching rate ratio A obtained by dividing the etching rate under the following condition (1) by the etching rate under the following condition (3) is 20 or more.

[Condition (1)] CF₄ and CHF₃ used as the fluorine-based gas

CF₄ flow rate: 150 sccm

CHF₃ flow rate: 50 sccm

Ar flow rate: 100 sccm

chamber pressure: 10 Pa

applied electric power: 400 W

temperature: 15° C.

[Condition (3)] O₂ used as the oxygen-based gas

O₂ flow rate: 400 sccm

Ar flow rate: 100 sccm

chamber pressure: 2 Pa

applied electric power: 400 W

temperature: 15° C.

### BRIEF DESCRIPTION OF DRAWINGS

FIG. 1 is a flow diagram showing a method for manufacturing a composition according to one embodiment of the present invention.

### DESCRIPTION OF EMBODIMENTS

The present inventors have found that increasing the content of the Q unit as a structural unit represented by the formula (B) in Patent Literature 1 (specifically, when trying to make the siloxane structural unit ratio represented by the Q unit in the total Si structural unit/(Q unit+T unit) (hereinafter, merely Q/(Q+T) ratio) be 0.60 or more) to increase the etching resistance to plasma of the oxygen-based gas, in the production process of the polysiloxane compound (A) (specifically, a Sol-gel polymerization reaction process), there is a case that a solid precipitated and a uniform composition cannot be obtained, the Q unit cannot be introduced at a high concentration by removing the precipitated solid to obtain the polysiloxane compound (A) which may result in the case of the Q/(Q+T) ratio being lower than 0.60. Note that the T unit means a Si structural unit in which 3 of the 4 bonds of the Si atoms are any of a siloxane bond, a silanol group, or a hydrolyzable group, and the remaining 1 bond is bonded to other groups.

Accordingly, in the present disclosure, it is one of the objects to provide a composition having a high content of the Q unit (specifically, a siloxane structural unit ratio represented by Q unit/(Q unit+T unit) in all Si structural units of 0.60 or more and less than 1.00).

Embodiments of the present invention will be described below. However, the present invention can be implemented in various modes without departing from the gist thereof, and should not be construed as being limited to the description of the following exemplary embodiments. Further, even if the operation and effect are different from those provided by the following embodiments, those apparent from the description of the present specification or those which can be easily predicted by those skilled in the art are naturally understood to be brought about by the present invention.

Hereinafter, a composition according to one embodiment of the present invention, a method for manufacturing a composition, a solution of a composition precursor, and a method for manufacturing a patterned substrate using the composition will be described in detail.

### [Composition]

The composition according to one embodiment of the present invention is a composition comprising a polysiloxane compound (A) containing a structural unit represented by formula (1) and a structural unit represented by formula (2),

wherein the siloxane structural unit ratio represented by Q unit/(Q unit+T unit) in all Si structural units is 0.60 or more and less than 1.00, and the solvent (B).

[(R¹)_{b}(R²)ₘ(OR³)ₗSiO_{n/2}] (1)

[In the formula, R¹ is a base represented by the following formula.

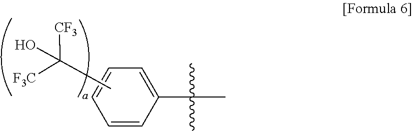

(a is the number of 1 to 5. The wavy line indicates that the intersecting line segment is a bond.)

R² is each independently a hydrogen atom, an alkyl group having 1 or more and 3 or less carbon atoms, a phenyl group, or a fluoroalkyl group having 1 or more and 3 or less carbon atoms, and R³ is each independently a hydrogen atom, or an alkyl group having 1 or more and to 3 or less carbon atoms. b is a number of 1 to 3, m is a number of 0 to 2, l is a number of 0 or more and less than 3, n is a number of more than 0 and 3 or less, and b+m+l+n=4.]

[(R⁴)ₚSiO_{q/2}] (2)

[In the formula, R⁴ is independently an alkoxy group having 1 or more and 3 or less carbon atoms, a hydroxyl group, or a halogen group, p is a number of 0 or more and less than 4, q is a number of more than 0 and 4 or less, and p+q=4.]

The above Q units are classified into the following five groups according to the substituents and bond states of the Si atoms.

Q⁰ unit: A structure in which all four bonds of Si atoms are hydrolyzable and polycondensable groups (groups capable of forming the siloxane bonds, such as halogen groups, alkoxy groups, or hydroxy groups).

Q¹ unit: A structure in which one of the four bonds of Si atoms forms the siloxane bond and the remaining three bonds are all hydrolyzable and polycondensable groups.

Q² unit: A structure in which two of the four bonds of Si atoms form the siloxane bonds and the remaining two bonds are all hydrolyzable and polycondensable groups.

Q³ unit: A structure in which three of the four bonds of Si atoms form the siloxane bonds and the remaining one is the hydrolyzable polycondensable group.

Q⁴ unit: A structure in which all four bonds of Si atoms form the siloxane bonds.

In addition, the above T unit is classified into the following 4 types depending on the substituent of Si atoms and the bonding state.

T⁰ unit: A structure in which three of four bonds of Si atoms are hydrolyzable and polycondensable groups (groups capable of forming the siloxane bond, such as a halogen group, an alkoxy group, or a hydroxy group), and the other one bond is another substituent (a group not capable of forming the siloxane bond).

T¹ unit: A structure in which one of the four bonds of the Si atom forms the siloxane bond, two bonds are hydrolyzable and polycondensable groups, and one bond is another substituent group.

T² unit: A structure in which two of the four bonds of Si atoms form the siloxane bond, one bond is the hydrolyzable polycondensable group, and one is another substituent.

T³ units: A structure in which three of the four bonds of Si atoms form the siloxane bond, one bond is another substituent.

In the composition according to one embodiment of the present invention, a solution state in which the polysiloxane compound (A) is dissolved in the solvent (B) is preferred. In addition, in some cases, a filler may be dispersed in the solution.

Here, in the structural unit represented by the above formula (1), b, m, l, n, as a theoretical value, b is an integer of 1 to 3, m is an integer of 0 to 2, l is an integer of 0 to 3, and n is an integer of 0 to 3. In addition, b+m+l+n=4 indicates that the sum of the theoretical values is 4. However, the values obtained by ²⁹Si NMR measurements are obtained by averaging b, m, l, and n, so that b may be a decimal fraction rounded to the nearest whole number between 1 to 3, m may be a decimal fraction rounded to the nearest whole number between 0 to 2, l may be a decimal fraction rounded to the nearest whole number which is more than 0 to 3 or less, and n may be a decimal fraction rounded to the nearest whole number which is more than 0 and 3 or less. Also, in formula (1), b is 1 to 3, preferably b is 1 to 2, and more preferably b is 1.

In the formula (1), n is more than 0 and 3 or less. Note that a state in which the composition is only a monomer (n=0) is not subject. Further, it is preferable that the amount of the monomer remaining in the composition is smaller, so that the molecular weight is easily increased in a later step, and a curing failure is hardly caused. In addition, when n is more than 0, a monomer may be contained in the composition. When the compositions contain monomers, the monomers are counted as T⁰ unit at Q/(Q+T) ratios.

In R¹, a is an integer of 1 to 5 as a theoretical value. However, in the values obtained by ²⁹Si NMR measurements, a may be a decimal fraction of 1 to 5. In R¹, a is preferably 1 or 2, and particularly preferably 1.

In the polysiloxane compound (1) represented by the above formula (1), it is preferable that R¹ is any of the following groups.

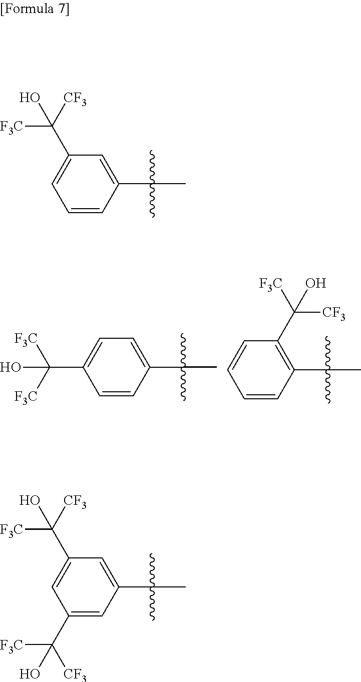

(The wavy line indicates that the intersecting line segment is a bond.)

In particular, the following groups are preferred.

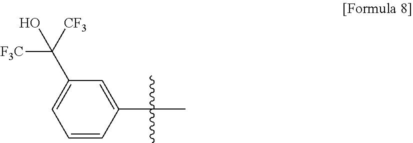 [SMILES: *c1cccc(C(O)(C(F)(F)F)C(F)(F)F)c1]

(The wavy line indicates that the intersecting line segment is a bond.)

In the formula (1), b is preferably 1.

In the formula (1), n is preferably 0.5 to 3, more preferably n is 0.7 to 3, and particularly preferably n is 0.9 to 3.

In the formula (2), q is more than 0 and 4 or less. Note that a state in which the composition is only a monomer (n=0) is not subject. Further, it is preferable that the amount of the monomer remaining in the composition is smaller, so that the molecular weight is easily increased in a later step, and a curing failure is hardly caused. In addition, when n is more than 0, a monomer may be contained in the composition. When the compositions contain monomers, the monomers are counted as Q⁰ units at Q/(Q+T) ratios.

A composition according to one embodiment of the present invention preferably has a pH of 1 or more and less than 6 at 25° C., more preferably a pH of 2 or more and 5 or less, and particularly preferably a pH of more than 2 and 5 or less. By setting the range of pH at 25° C. of the composition within the above range, it has an advantage that the weight average molecular weight (Mw) is more difficult to change and the storage stability is excellent.

A composition according to one embodiment of the present invention preferably has a viscosity of 0.5 mPa·s or more and 30 mPa·s or less at 25° C. When the viscosity is within the above range, it is preferable to control the film thickness when the composition is formed.

In addition, it is preferable that the number of insoluble substances having a particle size of 0.2 μm or more in a particle measurement by a light scattering type in-liquid particle detector in a liquid phase of the above composition is 100 or less per 1 mL of the composition. When the number of insoluble materials having a particle size of 0.2 μm or more is 100 or less per 1 mL of the composition, smoothness of the coating is hardly impaired, and unevenness and defects in etching are hardly generated. It should be noted that the smaller the number of particles larger than 0.2 μm, the more preferable, but may be 1 or more per 1 mL of the composition as long as it is within the above content range. The measurement of particles in the liquid phase in the composition according to the present invention is performed by using a commercially available measurement device of a light scattering type in-liquid particle measurement system using a laser as a light source. In addition, the particle diameter of a particle means a light scattering equivalent diameter of a PSL (latex made of polystyrene) standard particle reference.

Here, the above-mentioned particles are particles such as dust, organic solid matter, and inorganic solid matter contained as impurities in a raw material, particles such as dust, organic solid matter, and inorganic solid matter brought as contaminants during preparation of the composition, particles such as dust, organic solid matter, and inorganic solid matter, and particles precipitated during or after preparation of the composition. As described above, the above particles correspond to those which are finally present as particles without dissolving in the composition.

The composition of the present invention comprising the polysiloxane compound (A) and the solvent (B) is obtained by mixing and copolymerizing a solution of the composition precursor and at least one selected from a group consisting of chlorosilane, alkoxysilane, and a silicate oligomer, which gives a structural unit represented by the above formula (2).

### 1. (Solution of) Composition Precursor

A solution of the composition precursor is obtained by subjecting an HFIP group-containing aromatic halosilane represented by formula (4) (hereinafter, sometimes referred to as an HFIP group-containing aromatic halosilane (4)) or an HFIP group-containing aromatic alkoxysilane represented by formula (5) (hereinafter, sometimes referred to as an HFIP group-containing aromatic alkoxysilane (5)) or a mixture thereof, which is shown below, to hydrolysis polycondensation in a reaction solvent as needed.

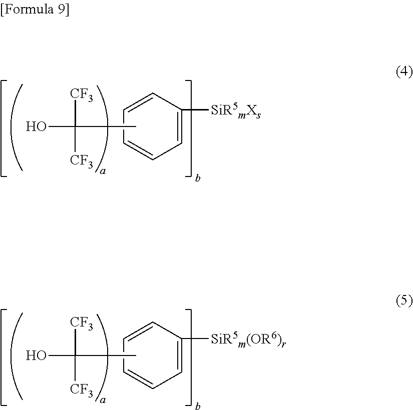

(In the formula, R⁵ is independently a hydrogen atom, an alkyl group having 1 or more and 3 or less carbon atoms, a phenyl group, a hydroxy group, a alkoxy group having 1 or more and 3 or less carbon atoms, or a fluoroalkyl group having 1 or more and 3 or less carbon atoms, X is a halogen atom, R⁶ is a hydrogen atom, or a linear alkyl group having 1 to 4 carbon atoms or branched alkyl group having 3 or 4 carbon atoms, and all or part of the hydrogen atoms in the alkyl group may be substituted with a fluorine atom. a is an integer of 1 to 5, b is an integer of 1 to 3, m is an integer of 0 to 2, s is an integer of 1 to 3, r is an integer of 1 to 3, and b+m+s=4 or b+m+r=4.)

1-1. Synthesizing the HFIP Group-Containing Aromatic Halosilane (4), which is a Raw Material for the Precursors

First, the process for synthesizing the HFIP group-containing aromatic halosilane (4) using an aromatic halosilane (6) as a raw material is explained. The aromatic halosilane (6) and a Lewis acid catalyst are collected in a reaction vessel, mixed, and hexafluoroacetone is introduced to perform a reaction, and the reactant is distilled and purified, whereby the HFIP group-containing aromatic halosilane (4) can be obtained.

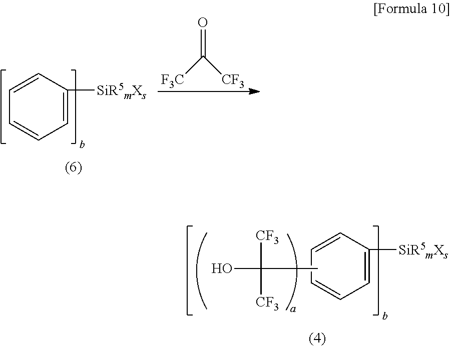

(In the formula, R⁵ is each independently a hydrogen atom, an alkyl group having 1 or more and 3 or less carbon atoms, a phenyl group, a hydroxy group, an alkoxy group having 1 or more and 3 or less carbon atoms or a fluoroalkyl group having 1 or more and 3 or less carbon atoms, X is a halogen atom, a is an integer of 1 to 5, b is an integer of 1 to 3, m is an integer of 0 to 2, s is an integer of 1 to 3, and b+m+s=4.)

### [Aromatic Halosilane (6)]

The aromatic halosilane (6) used as a raw material has a structure in which a phenyl group and a halogen atom directly bond to a silicon atom.

The aromatic halosilane (6) may have R⁵, a group directly bonded to a silicon atom, and examples of R⁵ include a hydrogen atom, an alkyl group having 1 or more and 3 or less carbon atoms, a phenyl group, a hydroxy group, an alkoxy group having 1 or more and 3 or less carbon atoms, or a fluoroalkyl group having 1 or more and 3 or less carbon atoms. Examples of such groups include a methyl group, an ethyl group, a propyl group, a butyl group, an isobutyl group, a t-butyl group, a neopentyl group, an octyl group, a cyclohexyl group, a trifluoromethyl group, a 1,1,1-trifluoropropyl group, a perfluorohexyl group, or a perfluorooctyl group. Among them, a methyl group is preferable as the substituent R⁵ because of availability.

The halogen atom X in the aromatic halosilane (6) includes fluorine atoms, chlorine atoms, bromine atoms, and iodine atoms, but from the availability and stability of the compound, X is preferably a chlorine atom.

As the aromatic halosilane (6), preferably, the following halosilanes can be exemplified.

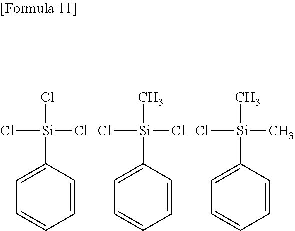

### [Lewis Acid Catalyst]

The Lewis acid catalyst used in the present reaction is not particularly limited, and examples thereof include aluminum chloride, iron (III) chloride, zinc chloride, tin (II) chloride, titanium tetrachloride, aluminum bromide, boron trifluoride, boron trifluoride diethyl ether complex, antimony fluoride, zeolites or composite oxides. Among them, aluminum chloride, iron (III) chloride, and boron trifluoride are preferred, and aluminum chloride is particularly preferred because of their high reactivity in the present reaction. The amount of the Lewis acid catalyst to be used is not particularly limited, but is 0.01 mol or more and 1.0 mol or less per 1 mol of the aromatic halosilane represented by formula (6).

### [Organic Solvent]

In the present reaction, when the aromatic halosilane (6) of the raw material is a liquid, a reaction can be carried out without using an organic solvent. However, when the aromatic halosilane (6) is a solid or has high reactivity, an organic solvent may be used. As the organic solvent, there is no particular limitation as long as it is a solvent in which the aromatic halosilane (6) is dissolved and does not react with the Lewis acid catalyst and the hexafluoroacetone, and pentane, hexane, heptane, octane, acetonitrile, nitromethane, chlorobenzene or nitrobenzene can be exemplified. These solvents may be used alone or in admixture.

### [Hexafluoroacetone]

Examples of the hexafluoroacetone used in the present reaction include hydrates such as hexafluoroacetone or hexafluoroacetone trihydrate. When these hydrates are used, hexafluoroacetone is preferably used as a gas because the yield decreases when moisture is mixed during the reaction. The amount of hexafluoroacetone to be used depends on the number of HFIP groups introduced into the aromatic ring, but is preferably 1 molar equivalent or more and 6 molar equivalent or less with respect to 1 mol of the phenyl group contained in the aromatic halosilane (6) of the raw material. In addition, when 3 or more HFIP groups are to be introduced into the phenyl group, an excessive amount of hexafluoroacetone, a large amount of catalysis, and a long reaction time are required. Therefore, it is more preferable that the amount of hexafluoroacetone to be used is set to 2.5 molar equivalents or less with respect to 1 mol of the phenyl group contained in the aromatic halosilane (6) of the raw material, and the number of HFIP groups introduced into the phenyl group is suppressed to 2 or less.

### [Reaction Conditions]

When synthesizing the HFIP group-containing aromatic halosilane (4), it is preferable to use a cooling device or a sealed reactor in order to keep the hexafluoroacetone in the reaction system because the boiling point of hexafluoroacetone is −28° C., and particularly, a sealed reactor is preferably used. When the reaction is carried out using a sealed reactor (autoclave), it is preferred to place the aromatic halosilane (6) and the Lewis acid catalyst in a sealed reactor first and then introduce a gas of hexafluoroacetone so that the pressure in the sealed reactor does not exceed 0.5 MPa.

The optimum reaction temperature in the present reaction varies greatly depending on the type of aromatic halosilane (6) of the raw material to be used, but is preferably carried out in a range of −20° C. or more and 80° C. or less. Further, as the electron density on the aromatic ring is large and the electrophilicity is high, it is preferable to perform the reaction at a lower temperature. By carrying out the reaction at a temperature as low as possible, cleavage of Ph-Si bond during the reaction can be suppressed, and the yield of the HFIP group-containing aromatic halosilane (4) is improved.

Although there is no particular limitation on the reaction time, it is appropriately selected depending on the amount of HFIP group introduced, the temperature, the amount of the catalyst used, and the like. Specifically, from the viewpoint of sufficiently proceeding the reaction, it is preferable to introduce hexafluoroacetone for 1 hour or more and 24 hours or less after introducing hexafluoroacetone.

After confirming that the raw material has been sufficiently consumed by a general-purpose analysis means such as gas chromatography, it is preferable to terminate the reaction. After termination of the reaction, the HFIP group-containing aromatic halosilane (4) can be obtained by removing the Lewis acid catalyst by means of filtration, extraction, distillation, or the like.

It is to be noted that there is a possibility that particles are also mixed in the synthesized precursor raw material. Therefore, it is preferable to filter the precursor raw material by a filter in order to remove particles or undissolved matter or the like after synthesis of the precursor raw material. Thus, particles contained in the precursor raw material can be reduced. Here, filter filtration is an operation in which a mixture of a solid mixed in a liquid is passed through a porous medium (filter medium) having many fine holes to separate solid particles larger than the holes from the liquid.

1-2. The HFIP Group-Containing Aromatic Halosilane (4) which is a Raw Material of the Composition Precursor

The HFIP group-containing aromatic halosilane (4) has a structure in which an HFIP group and a silicon atom are directly bonded to an aromatic ring.

The HFIP group-containing aromatic halosilane (4) is obtained as a mixture having a plurality of isomers having different numbers of substitutions and substitution positions of HFIP groups. The type of isomer and its abundance ratio which differ in the number of substitutions and substitution positions of HFIP group vary depending on the structure of the aromatic halosilane (6) of the raw material and the equivalent weight of the reacted hexafluoroacetone, but has any of the following partial structures as the main isomer.

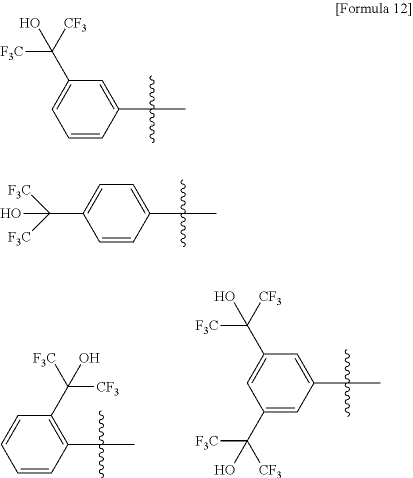

(Wavy line indicates that the intersecting line segment is a bond.)
1-3. Synthesis of HFIP Group-Containing Aromatic Alkoxysilane (5) which is a Raw Material of the Composition Precursor

Next, a step of using the HFIP group-containing aromatic halosilane (4) as a raw material and obtaining the HFIP group-containing aromatic alkoxysilane (5) will be described. Specifically, the HFIP group-containing aromatic halosilane (4) and an alcohol (referring to a R⁶OH described in the following reaction formula) are collected and mixed in a reaction vessel, and the following reaction for converting the chlorosilane into an alkoxysilane is performed, and the reaction product is distilled and purified, whereby the HFIP group-containing aromatic alkoxysilane (5) can be obtained.

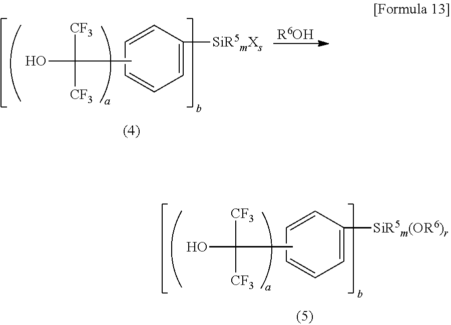

(In the formula, R⁵, R⁶, X, a, b, m, s, r are as described above, b+m+s=4 or b+m+r=4.)

The raw HFIP group-containing aromatic halosilane (4) can use a mixture of separated isomers and without precision distillation or the like, or a mixture of isomers without separation.

### [Alcohol]

The alcohol is appropriately selected depending on the alkoxysilane of interest. As R⁶, a linear alkyl group having 1 to 4 carbon atoms or a branched alkyl group having 3 or 4 carbon atoms, and all or a part of the hydrogen atoms in the alkyl group may be substituted with a fluorine atom. Specifically, examples include methanol, ethanol, 1-propanol, 2-propanol, 2-fluoroethanol, 2,2,2-trifluoroethanol, 3-fluoropropanol, 3,3-difluoropropanol, 3,3,3-trifluoropropanol, 2,2,3,3-tetrafluoropropanol, 2,2,3,3,3-pentafluoropropanol or 1,1,1,3,3,3-hexafluoroisopropanol. Particularly preferred is methanol or ethanol. When the alcohol is reacted, when moisture is mixed, the hydrolysis reaction and the condensation reaction of the HFIP group-containing aromatic halosilane (4) proceed, and the yield of the target HFIP group-containing aromatic alkoxysilane (5) decreases, so that it is preferable to use an alcohol having a small water content contained. Specifically, it is preferably 5% by mass or less, more preferably 1% by mass or less.

### [Reaction]

The reaction method in synthesizing a HFIP group-containing aromatic alkoxysilane (5) is not particularly limited. Typical examples include a method in which an alcohol is added dropwise to the HFIP group-containing aromatic halosilane (4) and reacted, or a method in which the HFIP group-containing aromatic halosilane (4) is added dropwise to an alcohol and reacted.

The amount of the alcohol to be used is not particularly limited, but is preferably 1 molar equivalent or more and 10 molar equivalents or less, more preferably 1 molar equivalent or more and 3 molar equivalents or less, based on Si—X bond contained in the HFIP group-containing aromatic halosilane (4), in terms of efficient progress of the reaction.

Although there is no particular limitation on the time for adding the alcohol or the HFIP group-containing aromatic halosilane (4), it is preferably 10 minutes or more and 24 hours or less, and more preferably 30 minutes or more and 6 hours or less. In addition, with respect to the reaction temperature during dropping, although the optimum temperature varies depending on the reaction conditions, specifically, it is preferably 0° C. or more and 70° C. or less.

By performing ripening while continuing stirring after completion of the dropping, the reaction can be completed. There is no particular limitation on the ripening time, and from the viewpoint of sufficiently advancing the desired reaction, it is preferably 30 minutes or more and 6 hours or less. In addition, it is preferable that the reaction temperature at the time of ripening is the same as that at the time of dropping or higher than that at the time of dropping. Specifically, 10° C. or higher and 80° C. or less is preferable.

Although the reactivity of the alcohol and the HFIP group-containing aromatic halosilane (4) is high and the halogenosilyl group is rapidly converted into an alkoxysilyl group, it is preferable to remove the hydrogen halide generated during the reaction in order to accelerate the reaction and suppress the side reaction. Methods for removing hydrogen halide in addition to the addition of known hydrogen halide scavengers such as amine compounds, orthoesters, sodium alkoxides, epoxy compounds, olefins, the hydrogen halide gas produced is removed from the system by heating or bubbling dry nitrogen. These methods may be performed alone or in combination.

Hydrogen halide scavengers may include orthoesters or sodium alkoxides. Examples of the orthoester include trimethyl orthoformate, triethyl orthoformate, tripropyl orthoformate, triisopropyl orthoformate, trimethyl orthoacetate, triethyl orthoacetate, trimethyl orthopropionate, and trimethyl orthobenzoate. From the ease of availability, it is preferably trimethyl orthoformate or triethyl orthoformate. Sodium methoxide or sodium ethoxide can be exemplified as the sodium alkoxide.

The reaction of the alcohol and the HFIP group-containing aromatic halosilane (4) may be diluted with a solvent. The solvent used is not particularly limited as long as it does not react with the alcohol and HFIP group-containing aromatic halosilane (4) used. Examples of the solvent used include pentane, hexane, heptane, octane, toluene, xylene, tetrahydro furan, diethyl ether, dibutyl ether, diisopropyl ether, 1,2-dimethoxyethane, or 1,4-dioxane. These solvents may be used alone or in admixture.

After confirming that the HFIP group-containing aromatic halosilane (4) as a raw material has been sufficiently consumed by a general-purpose analytical means such as gas chromatography, it is preferable to terminate the reaction. After completion of the reaction, the HFIP group-containing aromatic alkoxysilane (5) can be obtained by performing purification by a means such as filtration, extraction, distillation.

Among HFIP group-containing aromatic alkoxysilanes (5), HFIP group-containing aromatic alkoxysilanes represented by the formula (5-1) containing one aromatic ring and having b of the formula (5) being 1 can also produce a coupling reaction using a transition-metal catalyst such as rhodium, ruthenium, iridium using benzene substituted with a HFIP group and Y group and alkoxyhydrosilane as a raw material, according to the production method described in Japanese laid-open patent publication No. 2014-156461.

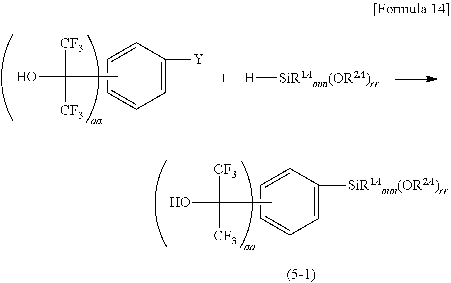

(In the formula, R^{1A} is independently a hydrogen atom, an alkyl group having 1 or more and 3 or less carbon atoms, a phenyl group, a hydroxy group, an alkoxy group having 1 or more and 3 or less carbon atoms, or a fluoroalkyl group having 1 or more and 3 or less carbon atoms, R^{2A} is independently a linear alkyl group having 1 to 4 carbon atoms or a branched alkyl group having 3 or 4 carbon atoms, all or a part of the hydrogen atoms in the alkyl group may be substituted with fluorine atoms, Y is chlorine atom s, bromine atoms, iodine atoms, —OSO₂(p-C₆H₄CH₃) group, or —OSO₂CF₃, aa is an integer of 1 to 5, mm is an integer of 0 to 2, rr is an integer of 1 to 3, and mm+rr=3.)

A polysiloxane compound (A) comprised in a composition according to one embodiment of the present invention preferably contains a structural unit obtained by hydrolysis polycondensation of 3-(2-hydroxy-1,1,1, 3,3,3-hexafluoroisopropyl)-triethoxysilyl benzene (hereinafter, it may be described as “HHFIPTESB”) because it is commonly used in the semiconductor industry.

### 1-4. Synthesis of (Solution of) Composition Precursor

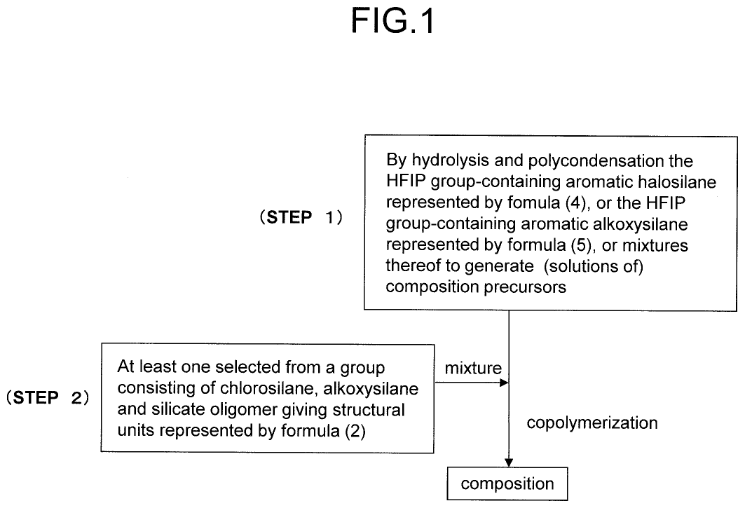

FIG. 1 is a flow diagram illustrating a method for manufacturing a composition according to one embodiment of the present invention. As shown in (STEP 1) in FIG. 1, the HFIP group-containing aromatic halosilane (4), or the HFIP group-containing aromatic alkoxysilane (5), or a mixture thereof, synthesized by the above process, is objected to hydrolysis polycondensation to obtain (a solution of) a composition precursor.

The present hydrolysis polycondensation reaction can be carried out in a general manner in the hydrolysis and polycondensation reaction of hydrolyzable silanes. Specifically, the HFIP group-containing aromatic halosilane (4), or the HFIP group-containing aromatic alkoxysilane (5), or a mixture thereof is collected in a reaction vessel. Thereafter, water for hydrolysis, if necessary, a catalyst for advancing the polycondensation reaction, and a reaction solvent are added into the reactor and stirred, and if necessary, heating is performed, and the hydrolysis and polycondensation reaction are allowed to proceed, whereby (a solution of) a composition precursor is obtained. It is to be noted that, even without the addition of a particular reaction solvent, those in which the composition precursor is miscible with water described above by hydrolysis and obtained as a uniform solution state are referred to as “the composition precursor solution.” Although the details are unknown, it is considered that, hydrolysis may contribute to the miscibility of a silanol group of a composition precursor derived from the above HFIP group-containing aromatic halosilane (4) or the HFIP group-containing aromatic alkoxysilane (5) with water described above. Further, it is considered that the by-produced solvent component (e.g., when an alkoxysilane is used, the corresponding alcohol is by-produced) contributes to the miscibility of the composition precursor with water described above. Further, a solvent similar to the reaction solvent described later may be further added to (the solution of) the composition precursor obtained by performing the above hydrolysis polycondensation.

### <Catalyst>

There is no particular limitation on the catalyst for proceeding the polycondensation reaction, and examples thereof include an acid catalyst and a base catalyst. Examples of the acid catalyst include a polyvalent carboxylic acid such as hydrochloric acid, nitric acid, sulfuric acid, hydrofluoric acid, phosphoric acid, acetic acid, trifluoroacetic acid, methanesulfonic acid, trifluoromethanesulfonic acid, camphoric acid, benzenesulfonic acid, tosylic acid, formic acid, maleic acid, malonic acid, or succinic acid, or anhydrides of these acids. Examples of the base catalyst include triethylamine, tripropylamine, tributylamine, tripentylamine, trihexylamine, triheptylamine, trioctylamine, diethylamine, triethanolamine, diethanolamine, sodium hydroxide, potassium hydroxide, or sodium carbonate.

### <Reaction Solvent>

In the hydrolysis and polycondensation reaction, it is not necessary to use a reaction solvent, and a raw material compound, water, and a catalyst can be mixed and subjected to hydrolysis polycondensation. On the other hand, when a reaction solvent is used, the type thereof is not particularly limited. Among them, a polar solvent is preferred, and an alcohol-based solvent is preferred more because of the solubility in the raw material compound, water, and catalyst. As the alcohol-based solvent, methanol, ethanol, 1-propanol, 2-propanol, 1-butanol, or 2-butanol can be exemplified.

Further, if necessary, a step of adjusting the pH of the solution of the composition precursor by extraction, water washing, or the like, may be performed after the reaction or a step of adjusting the concentration of the solution of the composition precursor by solvent distillation, concentration, dilution, or the like may be performed.

It is to be noted that there is a possibility that particles are also mixed into the solution of the synthesized composition precursor. Therefore, it is preferable to filter the solution of the composition precursor by a filter in order to remove particles or undissolved matter or the like after synthesis of the solution of the composition precursor. Thus, particles contained in the solution of the composition precursor can be reduced.

### 1-5. Solution of Composition Precursor

By synthesis of (the solution of) the composition precursor, the obtained composition precursor contains a structural unit represented by the following formula (3), and the pH of the solution of the composition precursor at 25° C. is 1 or more and 7 or less.

[(R¹)_{b}(R²)ₘ(OR³)ₛSiO_{t/2}] (3)

[In the formula, R¹ is a group represented by the following formula.]

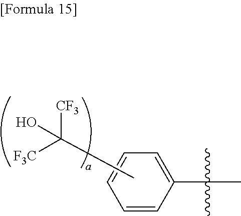

(a is the number of 1 to 5. The wavy line indicates that the intersecting line segment is a bond.)
R² is each independently a hydrogen atom, an alkyl group having 1 or more and 3 or less carbon atoms, a phenyl group, or a fluoroalkyl group having 1 or more and 3 or less carbon atoms, and R³ is each independently a hydrogen atom, or an alkyl group having 1 or more and 3 or less carbon atoms. b is a number of 1 to 3, m is a number of 0 to 2, s is a number of 0 or more and less than 3, t is a number of more than 0 and 3 or less, and b+m+s+t=4.]

In formula (3), a is an integer of 1 to 5 as a theoretical value. However, the values obtained by ²⁹Si NMR measurements may be decimal fractions of a 1 to 5. In addition, in formula (3), a is preferably 1 or 2.

Here, in the structural unit represented by the above formula (3), b, m, s, t, as theoretical values, b is an integer of 1 to 3, m is an integer of 0 to 2, s is an integer of 0 to 3, and t is an integer of 0 to 3. In addition, b+m+s+t=4 indicates that the sum of the theoretical values is 4. However, the values obtained by ²⁹Si NMR measurements are obtained by averaging b, m, s, and t, so that b may be a decimal fraction rounded to the nearest whole number between 1 to 3, m may be a decimal fraction rounded to the nearest whole number between 0 to 2, s may be a decimal fraction rounded to the nearest whole number which is 0 or more and less than 3, and t may be a decimal fraction rounded to the nearest whole number which is more than 0 and 3 or less.

In formula (3), R¹ is preferably any of the following groups.

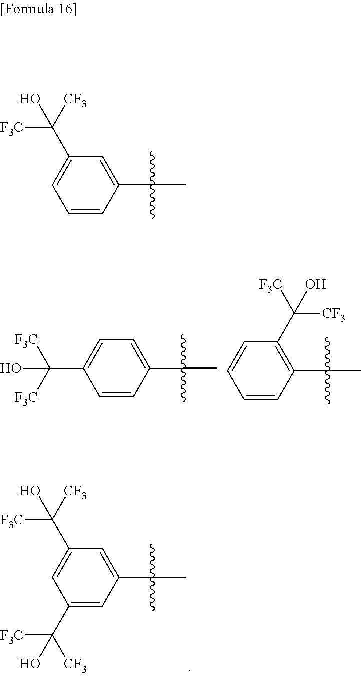

(The wavy line indicates that the intersecting line segment is a bond.)

Further, in formula (3), it is preferable that b is 1.

The weight average molecular weight of the above composition precursor is preferably 300 to 3000, more preferably 300 to 2000, and particularly preferably 300 to 1000. Note that, if the weight average molecular weight is 3000 or less, insoluble matter hardly occurs in a subsequent step, which is preferable.

### 2. Composition and Method for Manufacturing the Composition

First, a method for manufacturing a composition according to one embodiment of the present invention will be described. A composition according to one embodiment of the present invention is obtained by synthesizing the polysiloxane compound (A) by mixing and copolymerizing the solution of the composition precursor described in 1-5 and at least one selected from a group consisting of a chlorosilane, an alkoxysilane, and a silicate oligomer, which gives a structural unit represented by the following formula (2), as shown (in STEP 2) in FIG. 1. Note that the solvent (B) may be a solvent contained in a solution of the composition precursor, or may be contained in the composition by mixing the solvent (B) if necessary. Further, it is preferable that the polysiloxane compound (A) is dissolved in the solvent (B) and substantially uniformly dispersed.

[(R⁴)ₚSiO_{q/2}] (2)

[In the formula, R⁴ independently is an alkoxy group having 1 or more and 3 or less carbon atoms, a hydroxy group, or a halogen group, p is a number of 0 or more and less than 4, q is a number of more than 0 and 4 or less, and p+q=4.]

A method for mixing a solution of the composition precursor described in 1-5 with at least one selected from a group consisting of a chlorosilane, an alkoxysilane, and a silicate oligomer, providing a structural unit represented by formula (2) will be described below.

Here, a chlorosilane, an alkoxysilane, and a silicate oligomer which give a structural unit represented by the above formula (2) will be described.

### 2-1. Raw Materials Giving Structural Unit Represented by Formula (2)

### [Chlorosilane]

As chlorosilane, dimethyldichlorosilane, diethyldichlorosilane, dipropyldichlorosilane, diphenyldichlorosilane, bis (3,3,3-trifluoropropyl) dichlorosilane, methyl (3,3,3-trifluoropropyl) dichlorosilane, methyltrichlorosilane, ethyltrichlorosilane, propyltrichlorosilane, isopropyltrichlorosilane, phenyltrichlorosilane, trifluoromethyltrichlorosilane, pentafluoroethyltrichlorosilane, 3,3,3-trifluoropropyltrichlorosilane, or tetrachlorosilane can be exemplified.

### [Alkoxysilane]

As alkoxysilane, dimethyldimethoxysilane, diethyldimethoxysilane, dipropyldimethoxysilane, diphenyldimethoxysilane, bis(3,3,3-trifluoropropyl) dimethoxysilane, methyl (3,3,3-trifluoropropyl) dimethoxysilane, methyltrimethoxysilane, ethyltrimethoxysilane, propyltrimethoxysilane, isopropyltrimethoxysilane, phenyltrimethoxysilane, trifluoromethyltrimethoxysilane, pentafluoroethyltrimethoxysilane, 3,3,3-trifluoropropyltrimethoxysilane, tetramethoxysilane, or all or part of the methoxy group of those methoxysilane is at least one selected from a group consisting of an ethoxy group, a propoxy group, an isopropoxy group, and a phenoxy group, can be exemplified.

### [Silicate Oligomer]

The silicate oligomer is an oligomer obtained by hydrolysis polycondensation of tetraalkoxysilane, and examples of commercially available products include the trade name silicate 40 (average 5-mer, manufactured by TAMA CHEMICALS CO., LTD.), ethyl silicate 40 (average 5-mer, manufactured by COLCOAT CO., LTD.), silicate 45 (average 7-mer, manufactured by TAMA CHEMICALS CO., LTD.), M silicate 51 (average 4-mer, manufactured by TAMA CHEMICALS CO., LTD.), methylsilicate 51 (average 4-mer, manufactured by COLCOAT CO., LTD.), methylsilicate 53A (average 7-mer, COLCOAT CO., LTD.), ethyl silicate 48 (average 10-mer, manufactured by COLCOAT CO., LTD.), EMS-485 (mixture of ethylsilicate and methylsilicate, manufactured by COLCOAT CO., LTD.).

### 2-2. Solvent (B)

In the composition according to one embodiment of the present invention, a solvent (B) is used in addition to the polysiloxane compound (A). As the solvent (B), it should not dissolve or disperse the polysiloxane compound (A) and not precipitate it, and examples thereof include an ester-based, an ether-based, an alcohol-based, a ketone-based, and an amide-based solvent.

### [Ester-Based Solvent]

Examples of the ester-based solvent include acetate esters, basic esters, or cyclic esters. Propylene glycol monomethyl ether acetate (hereinafter sometimes referred to as PGMEA) as acetate esters, ethyl lactate as basic esters, and y-butyrolactone as cyclic esters can be exemplified.

### [Ether-Based Solvent]

As the ether-based solvent, butanediol monomethyl ether, propylene glycol monomethyl ether (hereinafter, sometimes referred to as PGME), ethylene glycol monomethyl ether, butanediol monoethyl ether, propylene glycol monoethyl ether, ethylene glycol monoethyl ether, butanediol monopropyl ether, propylene glycol monopropyl ether, and 1-propoxy-2-propanol can be exemplified.

### [Alcohol-Based Solvent]

Examples of the alcohol-based solvent include glycols. Examples of the glycols include ethylene glycol, diethylene glycol, triethylene glycol, propylene glycol, dipropylene glycol, butanediol, and pentanediol.

### [Ketone-Based Solvent]

As the ketone-based solvent, cyclohexanone which is a cyclic ketone can be exemplified.

### [Amide-Based Solvent]

As the amide-based solvent, N,N-dimethylformamide, N,N-dimethylacetamide, and N-methylpyrrolidone can be exemplified.

As the solvent (B) contained in the composition according to one embodiment of the present invention, at least one selected from a group consisting of PGMEA, PGME, and cyclohexanone is preferably used, since it is commonly used in the semiconductor industry.

The amount of a solvent (B) contained in a composition according to one embodiment of the present invention, with respect to 100 parts by mass of the polysiloxane compound (A), is 200 parts by mass or more and 100,000 parts by mass or less, preferably 400 parts by mass or more and 50,000 parts by mass or less. When the amount is 200 parts by mass or more, the polysiloxane compound (A) is hardly precipitated, and when the amount is 100,000 parts by mass or less, a coating film is easily formed without being too thin.

### 2-3. Other Components

In addition to the polysiloxane compound (A) and the solvent (B), other components may be added to a composition according to one embodiment of the present invention if necessary. Other components may include a surfactant, a silane coupling agent, an organic acid, and water, and may include a plurality of these other components.

As a component of a composition according to one embodiment of the present invention, the surfactant improves the effect of defoaming and leveling at the time of film formation, and the silane coupling agent improves adhesion to an upper resist layer and a lower organic layer. The organic acid improves the storage stability of the composition, and the addition of water improves the lithographic performance.

As the surfactant, a nonionic one is preferred, and examples thereof include perfluoroalkylpolyoxyethylene ethanol, fluorinated alkyl esters, perfluoroalkylamine oxides, or fluorine-containing organosiloxane-based compounds.

As the silane coupling agent, the structural unit represented by the following formula (7) can be exemplified. Although a specific example is given as a monomer in some cases described later, it is naturally possible to use an oligomer state in which a part of the monomer is hydrolyzed and polycondensed.

[(R_{y})_{c}R⁷ₑSiO_{f/2}] (7)

[In the formula, R^{y} is a monovalent organic group having a carbon number of 2 to 30 including any of an epoxy group, oxetane group, acryloyl group, methacryloyl group, and lactone group. R⁷ is a hydrogen atom, an alkylgroup having 1 or more and 3 or less carbon atoms, a phenyl group, hydroxy group, an alkoxy group having 1 or more and 3 or less carbon atoms, or a fluoroalkyl group having 1 or more and 3 or less carbon atoms, c is an integer of 1 to 3, e is an integer of 1 to 3, f is an integer of 0 to 3, and c+e+f=4. When there are a plurality of R_{y}, R⁷, each can take any of the above substituents independently.

In formula (7), it is particularly preferable that the value of c is 1 because of the availability. Specific examples of R⁷ include hydrogen atoms, methyl groups, ethyl groups, phenyl groups, methoxy groups, ethoxy groups, and propoxy groups.

When the R^{y} group of the structural unit represented by formula (7) contains an epoxy group, an oxetane group, or a lactone group, good adhesion to various substrates (including a substrate having a multilayer film) in which the outermost surface is silicon, glass, resin, or the like and good adhesion to the resist layer of the upper layer can be imparted to the cured film obtained from the composition. When the R^{y} group contains an acryloyl group or a methacryloyl group, a cured film having a higher curability can be obtained, and good solvent resistance can be obtained.

When the R^{y} group contains an epoxy group or an oxetane group, the R^{y} group is preferably a group represented by the following formula (2a), (2b), and (2c).

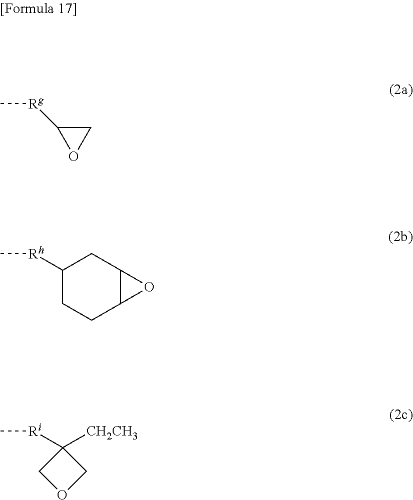

(In the formula, R^{g}, R^{h}, Rⁱ each independently stands for a divalent organic group. A dashed line represents a bond.)

Here, when R^{g}, R^{h} and Rⁱ are divalent organic groups, the divalent organics may include, for example, an alkylene group having 1 to 20 carbon atoms, and may include one or more sites forming an ether bond. When the number of carbon atoms is 3 or more, the alkylene group may be branched, and distant carbons may be linked to each other to form a ring. When the alkylene group is 2 or more, oxygen may be inserted between the carbon-carbon to contain one or more sites forming an ether bond, and as a divalent organic group, these are preferred examples.

In the repeating units of formula (7), when exemplifying a particularly preferred unit using alkoxysilane as the raw materials, 3-glycidoxypropyltrimethoxysilane (manufactured by Shin-Etsu Chemical Co., Ltd., product name: KBM-403), 3-glycidoxypropyltriethoxysilane (the same, product name: KBE-403), 3-glycidoxypropylmethyldiethoxysilane (the same, product name: KBE-402), 3-glycidoxypropylmethyldimethoxysilane (the same, product name: KBM-402), 2-(3,4-epoxycyclohexyl) ethyltrimethoxysilane (the same, product name: KBM-303), 2-(3,4-epoxycyclohexyl) ethyltriethoxysilane, 8-glycidoxyoctyltrimethoxysilane (the same, product name: KBM-4803), [(3-ethyl-3-oxetanyl) methoxy] propyltrimethoxysilane, [(3-ethyl-3-oxetanyl) methoxy] propyltriethoxysilane, and the like can be mentioned.

When the R^{y} group contains an acryloyl group or a methacryloyl group, it is preferably a group selected from the following formula (3a) or (4a).

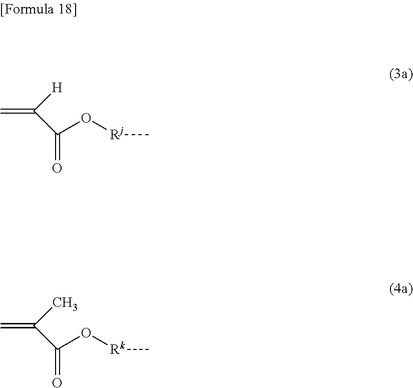

(In the formula, R^{j} and R^{k} each independently represent a divalent organic group. Dashed lines represent bonds.)

When R^{j} and R^{k} are divalent organic groups, those listed as preferred in R^{g}, R^{h}, Rⁱ can be listed again as preferred examples.

In the repeating units of formula (7), when exemplifying a particularly preferred unit using alkoxysilane as the raw materials, 3-methacryloxypropyltrimethoxysilane (manufactured by Shin-Etsu Chemical Co., Ltd., product name: KBM-503), 3-methacryloxypropyltriethoxysilane (the same, product name: KBE-503), 3-methacryloxypropylmethyldimethoxysilane (the same, product name: KBM-502), 3-methacryloxypropylmethyldiethoxysilane (the same, product name: KBE-502), 3-acryloxypropyltrimethoxysilane (the same, product name: KBM-5103), and 8-methacryloxyoctyltrimethoxysilane (the same, product name: KBM-5803) can be mentioned.

If the R^{y} group contains a lactone group, and if expressed in a R^{y}—Si construct, it is preferably a group selected from the following formulas (5-1) to (5-20), formulas (6-1) to (6-7), formulas (7-1) to (7-28), or formulas (8-1) to (8-12).

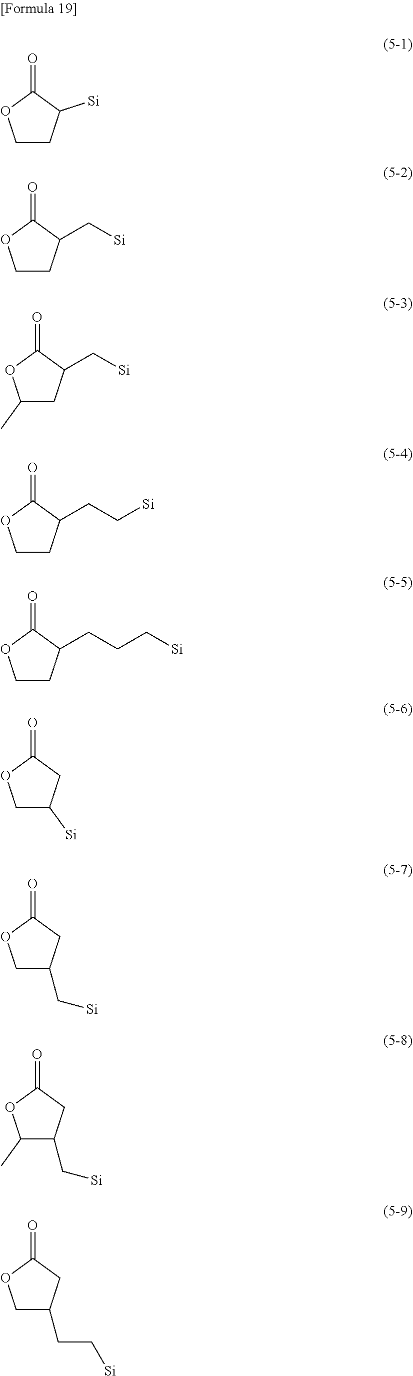

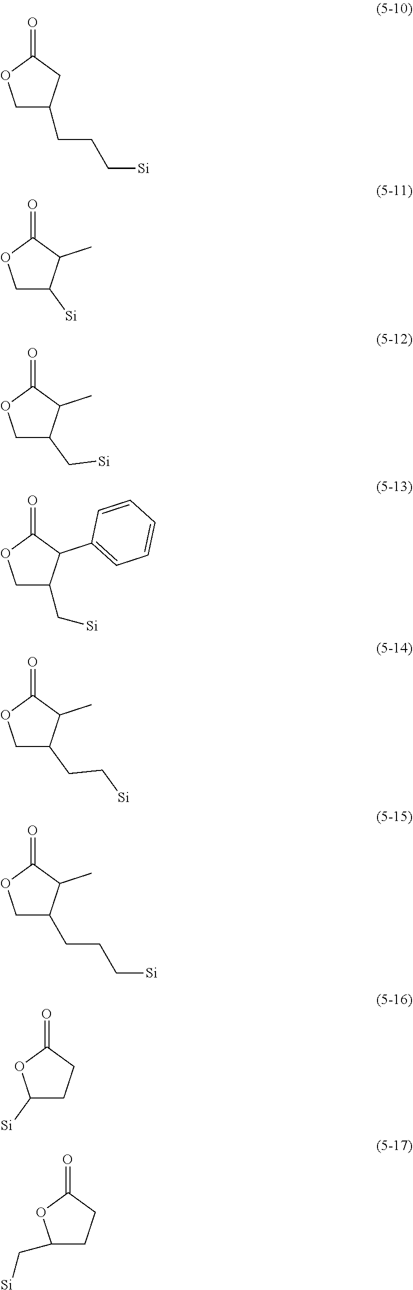

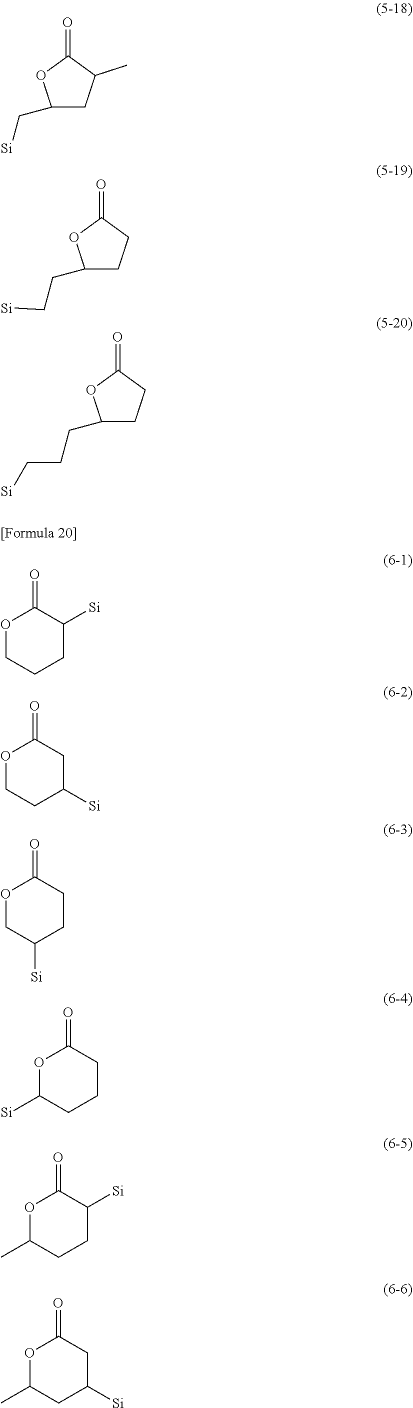

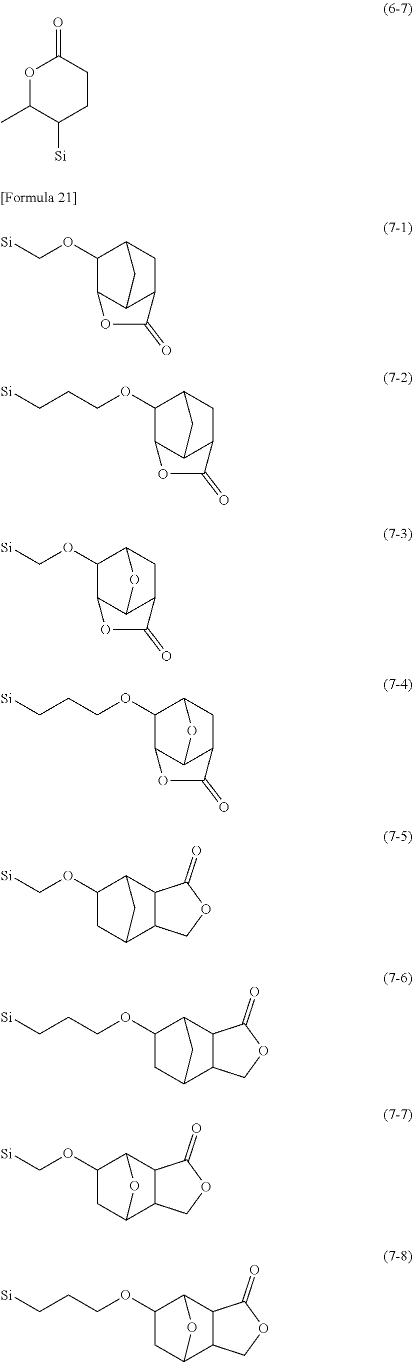

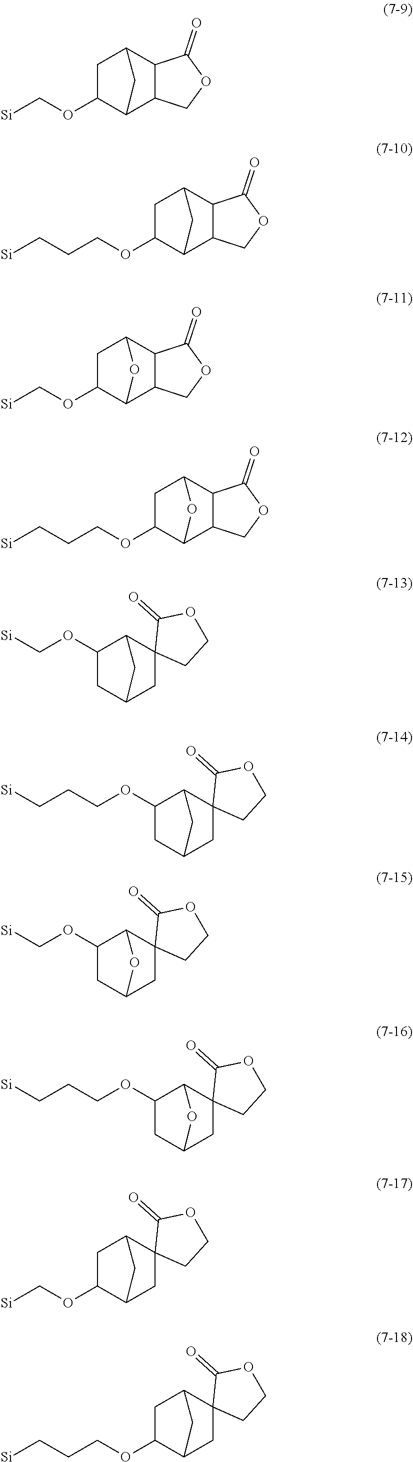

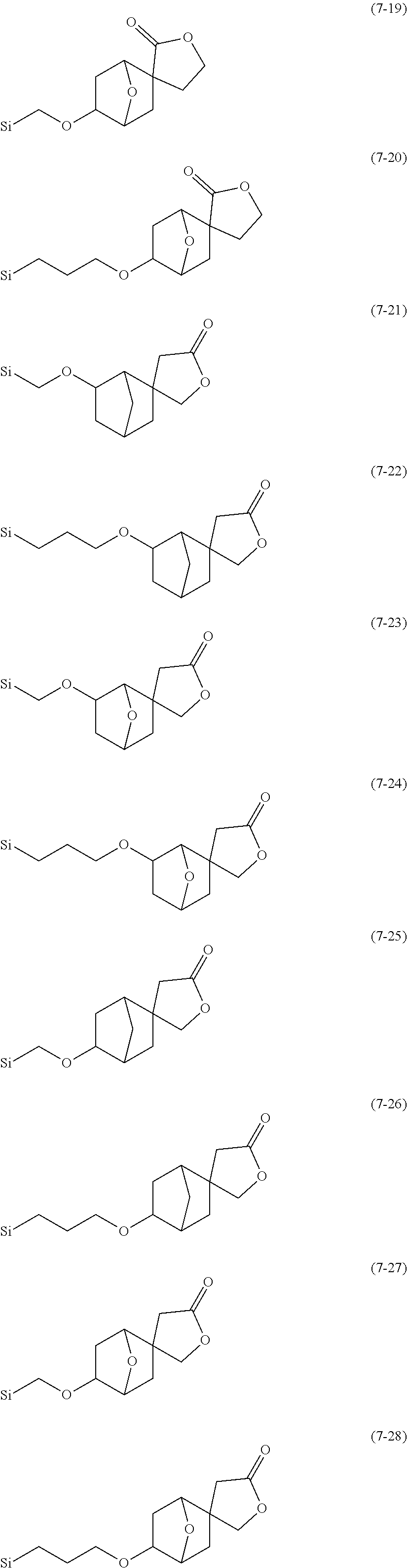

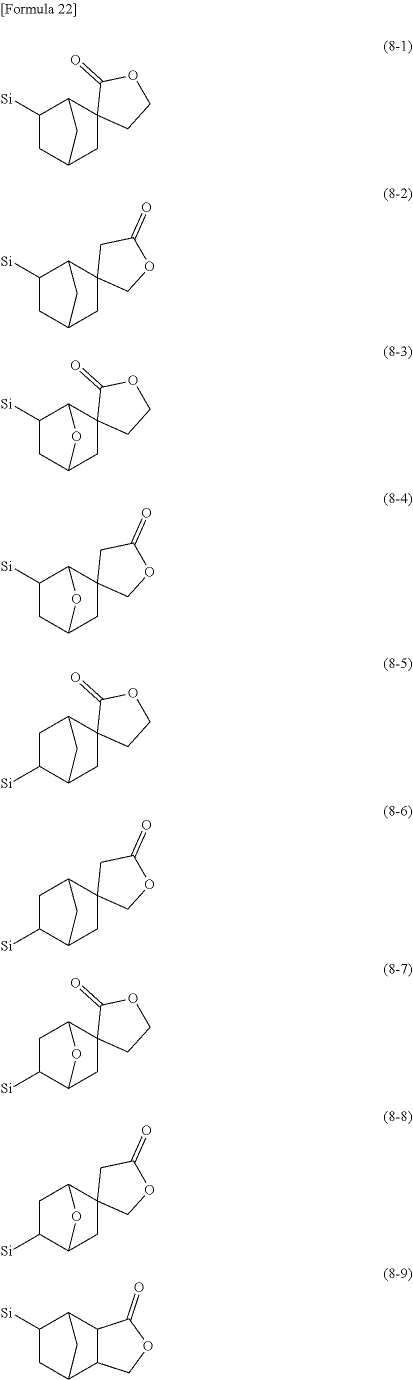

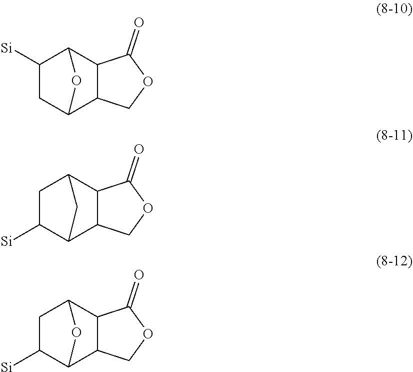

As the organic acid, an acid having 1 or 2 or more valences having 1 to 30 carbon atoms is preferably added. Specifically, formic acid, acetic acid, maleic acid, citric acid, oxalic acid, and propionic acid, are mentioned and particularly, acetic acid and maleic acid are preferred. In addition, in order to maintain stability, 2 or more kinds of acids may be mixed and used. The amount added is preferably added in terms of the pH of the composition so that the pH at 25° C. is 3 or more and 5 or less.

The amount of water added may be 0% by mass or more and less than 50% by mass, and may be 0% by mass to 30% by mass, or even 0% by mass to 20% by mass, with respect to the solvent component of the composition.

In addition, as one embodiment of the present invention, in the method for manufacturing a composition described above, a predetermined solvent may be added when the above precursor and at least one selected from a group consisting of chlorosilane, alkoxysilane, and a silicate oligomer, which gives a structural unit represented by the above formula (2), are copolymerized (STEP 2 in FIG. 1). As used herein, a solvent species or a solvent (B) listed in <reaction solvent> of “1-4. (Solution of) composition precursor” described above can be used as the predetermined solvent. As the solvent (B), it should not dissolve or disperse the polysiloxane compound (A) and not precipitate it, and examples thereof include an ester type, an ether type, an alcohol type, a ketone type, or an amide type solvent. Note that the above-mentioned <reaction solvent> and the solvent (B) may be added to the above precursor in advance. Further, it may be added to at least one selected from a group consisting of chlorosilane, alkoxysilane, and a silicate oligomer described above in advance. Further, it may be added at the time of preparing the above copolymerization reaction. Further, it may be added in the middle of the above copolymerization reaction. It is preferable to add a predetermined solvent to a raw material of the above-mentioned copolymerization in advance or to add it at the time of preparing the above-mentioned copolymerization reaction because of a homogeneous reaction. For example, the above-mentioned <reaction solvent> and the solvent (B) may be added together, and the <reaction solvent> may be distilled off after the above copolymerization. For example, the above-mentioned <reaction solvent> may be added, and after the above copolymerization, the <reaction solvent> may be distilled off to add the solvent (B).

In addition, as one embodiment of the present invention, in the method for manufacturing a solution of the above composition precursor, the HFIP group-containing aromatic halosilane (4) or an HFIP group-containing aromatic alkoxysilane (5), which is a raw material compound of the above precursor, and a silane coupling agent described above may be copolymerized.

In addition, as one embodiment of the present invention, in the method for manufacturing the above composition, a silane coupling agent described above may be added when the above precursor and at least one selected from a group consisting of chlorosilane, alkoxysilane, and a silicate oligomer, which gives a structural unit represented by the above formula (2), are copolymerized. The above silane coupling agent may be added to a solution of a precursor in advance, or may be added to at least one selected from a group consisting of chlorosilane, alkoxysilane, and a silicate oligomer in advance, or may be added after mixing both.

According to the method for manufacturing a composition according to one embodiment of the present invention, a uniform composition can be obtained without precipitating a solid during the course of copolymerization. Thus, the Q unit can be introduced at a high concentration, and the Q/(Q+T) ratio can be 0.6 or more and less than 1.00. Further, although details are unknown, it is considered that the OH of the 2-hydroxy-1, 1,1, 3, 3, 3-hexafluoroisopropyl group increases compatibility when the Q unit is introduced at a high concentration, so that the polymerization giving the structural unit represented by formula (1) and the polymerization giving the structural unit represented by formula (2) do not occur in a biased manner, respectively, but both polymerizations tend to occur uniformly, so that both structural units can be uniformly present without bias in the composition. In particular, it is believed that a more significant contribution is obtained in the method for manufacturing of the present invention via a solution of the composition precursor.

Further, a silane coupling agent may be further added to the composition obtained by the above production method. In this case, as the silane coupling agent, the silane coupling agent described above can be used. Specific silane coupling agents will be exemplified below.

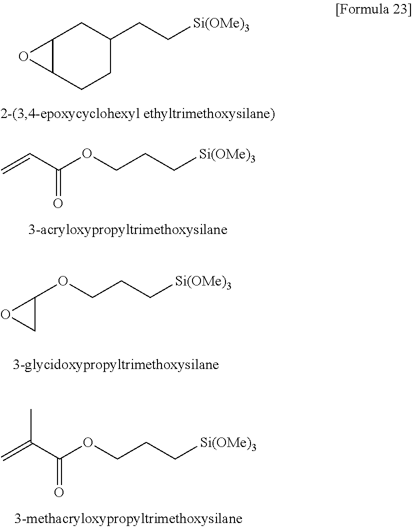

In addition, in the method for manufacturing a composition according to one embodiment of the present invention, a composition having a different Q/(Q+T) ratio may be blended. For example, a composition having a Q/(Q+T) ratio of 0.7 and a composition having a Q/(Q+T) ratio of 0.9 may be blended to produce a composition having a Q/(Q+T) ratio of 0.6 or more and less than 1.00. Alternatively, for example, a composition having a Q/(Q+T) ratio of 0.6 or more and less than 1.00 and a composition having a Q/(Q+T) ratio of less than 0.6 may be blended to produce a composition having a Q/(Q+T) ratio of 0.6 or more and less than 1.00.

After adding the silane coupling agent mentioned above to the solution of the above composition precursor, at least one selected from a group consisting of chlorosilane, alkoxysilane, and a silicate oligomer which give a structural unit represented by the following formula (2) may be further mixed and copolymerized.

A solution of the above composition precursor, at least one selected from a group consisting of a chlorosilane, an alkoxysilane, and a silicate oligomer, which gives a structural unit represented by the following formula (2), and a silane coupling agent described above may be mixed and copolymerized.

It is to be noted that there is a possibility that particles are also mixed in the composition synthesized as described above. Therefore, it is preferable to filter the composition with a filter in order to remove particles or undissolved matter or the like after synthesis of the composition.

### 3. Application of Composition According to One Embodiment of the Present Invention

The composition according to one embodiment of the present invention can also be used as a resist layer of a multilayer film resist method. When a composition according to one embodiment of the present invention is used for a resist layer, a photoacid generator which generates an acid by exposure, a basic substance which suppresses diffusion of an acid, a quinonediazide compound which forms an indenecarboxylic acid by exposure, a crosslinking agent which reacts with a base polymer by the action of an acid, and the like are added as further components. In this way, a function as a resist is developed by exposure and combined with the organic layer. According to lithography, a pattern is obtained by exposure to a resist layer containing a composition according to one embodiment of the present invention. Thereafter, dry etching is performed by plasma of an oxygen-based gas through the pattern to form a pattern in the organic layer. Thereafter, dry etching of the substrate is performed by plasma of a fluorine-based gas or a chlorine-based gas through the patterned organic layer, whereby a substrate on which a pattern as a target object is formed is obtained.

### 4. Method for Manufacturing Patterned Substrate Using Composition

In the multilayer resist method, a multilayer film consisting of a resist layer (upper layer) and an under layer film (under layer) is formed on an organic layer formed on a substrate to produce a patterned substrate. As described above, after patterning of the resist layer in accordance with lithography, the pattern is masked, and through dry etching to the under layer film, a substrate to which the pattern is finally transferred is obtained. A composition according to one embodiment of the present invention can be used as the above under layer film.

In other words, a manufacturing method for a patterned substrate according to one embodiment of the present invention includes an organic layer, the under layer film formed on the organic layer using a cured product of the composition according to one embodiment of the present invention, a first step of obtaining a pattern wherein a resist layer is exposed with a high energy ray through a photomask to the substrate with the multilayer film and then the resist layer is developed with a developer, a second step of dry etching the under layer film through the pattern of the resist layer to obtain a pattern in the under layer film, a third step of dry etching an organic layer through the pattern of the under layer film to obtain a pattern in the organic layer, and a fourth step of dry etching the substrate through the pattern of the organic layer to obtain a pattern in the substrate.

It is preferable to perform dry etching of the under layer film with a fluorine-based gas in the second step, perform dry etching of the organic layer with an oxygen-based gas in the third step, and perform dry etching of the substrate with a fluorine-based gas or a chlorine-based gas in the fourth step. Hereinafter, each element will be described in detail.

### [Substrate]

The substrate material for contacting the above composition includes a substrate made of silicon, amorphous silicon, polycrystalline silicon, silicon oxide, silicon nitride, silicon oxynitride, or the like, substrates forming metal films such as tungsten, tungsten-silicon, aluminum, copper, or the like, a low dielectric constant film, and an insulating film are formed on these substrates. Alternatively, the substrate may have a multilayer structure, and the outermost surface thereof may be a substrate having the above material. The film formed on the substrate usually has a film thickness of 50 nm or more and 20000 nm or less.

On these substrates, as the multilayer film, an organic layer, a cured product (under layer) using a composition according to one embodiment of the present invention on the organic layer, and a resist layer (upper layer) are sequentially formed on the cured product, thereby obtaining the above substrate with a multilayer film.

### [Organic Layer]

On the substrate, a film made from novolac resin, epoxy resin, urea resin, isocyanate resin or polyimide resin having phenolic structure, bisphenol structure, naphthalene structure, fluorene structure, carbazole structure, and the like, is formed as an organic layer. It is possible to form an organic layer by coating an organic layer forming composition containing these resins on a substrate by spin coating or the like. The organic layer having an aromatic ring in the structure exhibits an anti-reflection function when the resist layer is exposed to form a pattern in the resist layer. Further, when the intermediate layer is dry-etched by the fluorine-based gas via a pattern obtained in the resist layer which is a subsequent step, sufficient etching resistance of the fluorine-based gas to plasma is exhibited. Further, it contributes to a reduction of outgas by containing an aromatic ring having high heat resistance. The thickness of the organic layer varies depending on the etching conditions at the time of dry etching, and is not particularly limited, but is usually 5 nm or more and 20000 nm or less.

### [Under Layer Film]

A coating film of an under layer film can be formed by coating a composition according to one embodiment of the present invention on the organic layer by spin coating or the like. After the coating film of the under layer film, in order to prevent mixing in which the resist layer and the under layer film are mixed in a later step, it is preferable that the coating film is heated to 100° C. or more and 400° C. or less and cured. The thickness of the under layer film varies depending on the type of the fluorine-based gas used during dry etching and the etching conditions, and is not particularly limited, but is usually formed so as to be 5 nm or more and 500 nm or less.

The under layer film formed using a composition according to one embodiment of the present invention has a high content of the Q unit in the structure. Therefore, the etching resistance of the oxygen-based gas to plasma can be increased.

### [Resist Layer (Upper Layer)]

On top of the under layer film, a multilayer film is completed by forming a resist layer by forming a film of a resist composition by spin coating or the like. According to lithography, a high energy ray, for example, an ultraviolet ray such as the g-line, i-line, KrF excimer laser light, ArF excimer laser or EUV described above is exposed through a photomask, the exposed portion is solubilized (in the case of a positive resist) in the developer or insolubilized (in the case of a negative type) to obtain a pattern in the resist layer. Usually, an aqueous solution of tetramethylammonium hydroxide is used as the developer. In the organic solvent development of a negative resist, butyl acetate is used as the developer. As the resist composition, it is sufficient that a resist layer sensitive to the ultraviolet light can be formed, and can be appropriately selected depending on the wavelength of ultraviolet light. In the method for manufacturing a patterned substrate according to one embodiment of the present invention, it is preferable that the high energy ray has a wavelength of ultraviolet rays of 1 nm or more and 400 nm or less.

In addition to the base resin, a known resist obtained by adding a photoacid generator which generates an acid by exposure and a basic substance which suppresses diffusion of an acid can be used for the resist composition.

Examples of the base resin include polymethacrylate, a copolymer of cyclic olefin and maleic anhydride, polynorbornene, polyhydroxystyrene, novolac resin, phenolic resin, maleimide resin, polyimide, polybenzoxazole, polysiloxane, and polysilsesquioxane.

As the photoacid generator, a compound which generates an acid such as sulfonic acid, fluorosulfonic acid, fluorophosphoric acid, or fluoroantimony acid by exposure can be exemplified. In the case of a negative resist, an additive such as a crosslinking agent which reacts with the base resin by the action of an acid is added.

Specific examples of the photoacid generator include sulfonium salts, iodonium salts, sulfonyldiazomethanes, N-sulfonyloxyimides or oxime-0-sulfonates. These photoacid generators may be used alone or in combination of 2 or more thereof. Specific examples of commercially available products include, but are not limited to, trade name: Irgacure PAG121, Irgacure PAG103, Irgacure CGI1380, and Irgacure CGI725 (manufactured by BASF SE), trade name: PAI-101, PAI-106, NAI-105, NAI-106, TAZ-110, TAZ-204 (manufactured by Midori Kagaku Co., Ltd.), trade name: CPI-200K, CPI-210S, CPI-101A, CPI-110A, CPI-100P, CPI-110P, CPI-100TF, CPI-110TF, HS-1, HS-1A, HS-1P, HS-1N, HS-1TF, HS-1NF, HS-1MS, HS-1CS, LW-S1, LW-S1NF (manufactured by San-Apro Ltd.), trade name: TFE-triazine, TME-triazine, or MP-triazine (manufactured by SANWA CHEMICAL CO., LTD.).

### [Pattern Formation]

In the pattern formed in the resist layer, the under layer film is exposed at a portion dissolved and removed in the developer. A portion where the under layer film is exposed is subjected to dry etching by plasma of a fluorine-based gas such as a fron-based gas. In the dry etching, the under layer film formed from a composition according to one embodiment of the present invention has a high etching rate with respect to the plasma of the fluorine-based gas, and the resist layer forming the pattern has a low etching rate, so that sufficient etching selectivity can be obtained.

Next, by using the pattern formed on the resist layer as a mask, the pattern is transferred to the under layer film.

Next, using the patterned under layer film as a mask, dry etching of the organic layer is performed using plasma of an oxygen-based gas as an etching gas. In this way, a pattern transferred to the organic layer is formed. The under layer film formed from the composition according to one embodiment of the present invention has high etching resistance to plasma of an oxygen-based gas. Therefore, sufficient etching selectivity is obtained.

Finally, the patterned organic layer is subjected to dry etching of the substrate by plasma of a fluorine-based gas or a chlorine-based gas to obtain a substrate on which a pattern as an object is formed.

### [Etching Gas]

Examples of the fluorine-based gas or the chlorine-based gas used in a manufacturing process of a patterned substrate according to one embodiment include, but are not limited to, CF₄, CHF₃, C₃F₆, C₄F₆, C₄F₈, chlorine trifluoride, chlorine, trichloroborane, and dichloroborane. As the oxygen-based gas, O₂, CO, CO₂ can be mentioned, from the safety point of view, O₂, CO, CO₂ is preferred.

In a composition according to one embodiment of the present invention, the etching rate ratio A obtained by dividing the etching rate under the following condition (1) by the etching rate under the following condition (2) is 50 or more, preferably 60 or more, more preferably 70 or more.

[Condition (1)] CF₄ and CHF₃ used as the fluorine-based gas

CF₄ flow rate: 150 sccm

CHF₃ flow rate: 50 sccm

Ar flow rate: 100 sccm

chamber pressure: 10 Pa

temperature: 15° C.

[Condition (2)] CO₂ used as the oxygen-based gas

CO₂ flow rate: 300 sccm

Ar flow rate: 100 sccm

N₂ flow rate: 100 sccm

chamber pressure: 2 Pa

applied Power: 400 W

temperature: 15° C.

A composition according to one embodiment of the present invention, etching rate ratio B, which is the etching rate under the following condition (1) divided by the etching rate under the following condition (3), is 20 or more, preferably 50 or more, more preferably 52 or more, particularly preferred 55 or more.

[Condition (1)] CF₄ and CHF₃ used as the fluorine-based gas

CF₄ flow rate: 150 sccm

CHF₃ flow rate: 50 sccm

Ar flow rate: 100 sccm

chamber pressure: 10 Pa

applied electric power: 400 W

temperature: 15° C.

[Condition (3)] O₂ used as the oxygen-based gas

O₂ flow rate: 400 sccm

Ar flow rate: 100 sccm

chamber pressure: 2 Pa

applied electric power: 400 W

temperature: 15° C.

Except for the under layer film of the multilayer film, a composition according to one embodiment of the present invention is excellent in solvent resistance, adhesion, transparency, and heat resistance of the cured film obtained by increasing the Q unit content. Therefore, a composition according to one embodiment of the present invention can be applied to a protective film for a semiconductor, a protective film for an organic EL or a liquid crystal display, a coating agent for an image sensor, a planarizing material and a microlens material, an insulating protective film material for a touch panel, a planarizing material for a liquid crystal display TFT, a material for forming a core or a cladding of an optical waveguide, and the like.

### EXAMPLES

Hereinafter, the present invention will be specifically described with examples, but the present invention is not limited by these examples.

Analysis of a composition precursor and a composition obtained in this example was carried out by the following method.

### [Weight Average Molecular Weight Measurement]

The weight average molecular weight (Mw) of the composition precursor, which will be described later, and the composition was measured as follows. A high-performance GPC device manufactured by Tosoh Corporation, an instrument name HLC-8320GPC, a TSKgel SuperHZ2000 manufactured by Tosoh Corporation as a column, and tetrahydrofuran (THF) as a solvent were used, and measured by polystyrene conversion.

### [pH Measurement]

The pH of the solution of the composition precursor described later and the composition at about 25° C. were measured with pH test papers.

### [Si-NMR Analysis of Composition Precursor]

A composition precursor described later was measured with methoxytrimethylsilane as an internal standard by using a nuclear magnetic resonance device (manufactured by JEOL Ltd., instrument name: JNM-ECA400) having a resonance frequency of 400 MHz.

From the area ratio of each peak derived from the T unit, s and t of the formula (3) were obtained. Since the R¹ group and R² group are groups that do not participate in hydrolysis and polycondensation reactions, the numbers b and m of these groups hardly vary in the process of synthesizing the precursors. Therefore, the ratio of the preparation of b and m was adopted as it was.

### [Calculation of Q/(Q+T) Ratios by Si-NMR Analysis of Compositions]

The compositions described below were measured with methoxytrimethylsilane as an internal standard by using a nuclear magnetic resonance device (manufactured by JEOL Ltd., instrument name: JNM-ECA400) having a resonance frequency of 400 MHz.

The Q/(Q+T) ratio was calculated from the total area of the peaks derived from the T unit and the total area of the peaks derived from the Q unit obtained by the above measurement. In addition, l and n in formula (1) were obtained from the area ratio of each peak derived from the T unit. In addition, p and q in formula (2) were obtained from the area ratio of each peak derived from the Q unit.

### [Storage Stability Test of Composition]

The composition described later was subjected to the above weight average molecular weight measurement before and after being stored at 5° C. for 1 week.

### Example 1

To a 50 mL flask was added 3.66 g (9 mmol) of the synthesized 3-(2-hydroxy-1,1,1, 3,3,3-hexafluoroisopropyl)-triethoxysilylbenzene (HHFIPTESB), 0.7 g (39 mmol) of water, 0.09 g (1.5 mmol) of acetic acid, and the mixture was heated to 40° C. and stirred for 1 hour to obtain a solution of a composition precursor as a homogeneous solution.

In a solution of the above composition precursor, 3.13 g (21 mmol [in terms of SiO₂ contained in silicate 40. (Silicate 40 itself is about 4.2 mmol: as a 5-mer)]) of silicate 40 (average 5-mer, manufactured by TAMA CHEMICALS CO., LTD.) was added and stirred at 40° C. for 4 hours. No insoluble matter occurred during agitation and the reaction solution was in a solution state. After stirring, a propylene glycol monomethyl ether acetate (PGMEA) solvent was added, and water, acetic acid, and by-produced ethanol and a part of PGMEA were distilled off using a rotary evaporator under reduced pressure at 60° C., and filtered under reduced pressure to obtain 40 g of a polysiloxane compound solution (composition) having a solid concentration of 10% by mass.

### Example 2

40 g of a polysiloxane compound solution (composition) having a solid concentration of 10% by mass was obtained by the same procedure as in example 1, except that the temperature was increased to 70° C. after the addition of silicate 40 and stirred for 2 hours.

### Example 3

3.25 g (8 mmol) of synthesized 3-(2-hydroxy-1,1,1,3,3,3-hexafluoroisopropyl)-triethoxysilylbenzene (HHFIPTESB), 4.81 g (100 mmol) of ethanol, 1.81 g (100 mmol) of water, 0.12 g (2 mmol) of acetic acid, were added to the 50 mL flask, warmed to 80° C., and stirred for 1 hour to obtain a solution of a composition precursor which is a homogeneous solution.

In a solution of the above composition precursor, 4.77 g (32 mmol [in terms of SiO₂ contained in silicate 40. (Silicate 40 itself is about 6.4 mmol: as a 5-mer)]) of silicate 40 (average 5-mer, manufactured by TAMA CHEMICALS CO., LTD.) was added and stirred at 80° C. for 4 hours. No insoluble matter occurred during agitation and the reaction solution was in a solution state. After stirring, the propylene glycol monomethyl ether acetate (PGMEA) solvent was added, and water, acetic acid, and by-produced ethanol and a part of PGMEA were distilled off using a rotary evaporator under reduced pressure at 60° C., and filtered under reduced pressure to obtain 40 g of a polysiloxane compound solution (composition) having a solid concentration of 10% by mass.

### Example 4

4.06 g (10 mmol) of synthesized HHFIPTESB, 87.38 g (1.9 mol) of ethanol, 43.69 g (2.4 mol) of water, 0.58 g (5 mmol) of maleic acid were added to a 200 mL flask, heated to 80° C., stirred for 1 hour, to obtain a solution of the composition precursor which is a uniform solution.

In a solution of the above composition precursor, 13.41 g (90 mmol [in terms of SiO₂ contained in silicate 40. (Silicate itself is about 18 mmol: as a 5-mer)]) of silicate 40 (average 5-mer, manufactured by TAMA CHEMICALS CO., LTD.) was added and stirred at 80° C. for 4 hours. No insoluble matter occurred during agitation and the reaction solution was in a solution state. After stirring, water and by-produced ethanol were distilled off using a rotary evaporator under reduced pressure at 60° C. Thereafter, 80 g of cyclohexanone was added and then transferred to a separatory funnel, and 80 g of water was added thereto, followed by a first water washing. An additional 80 g of water was added to perform a second water washing. Thereafter, concentration was performed using a rotary evaporator while reducing the pressure of the reaction solution transferred from the separatory funnel to the flask at 60° C., and then filtered under reduced pressure to obtain 37 g of a polysiloxane compound solution (composition) having a solid concentration of 10% by mass.

### Comparative Example 1

8.13 g (20 mmol) of synthesized HHFIPTESB, 2.98 g (20 mmol [converted to SiO₂ contained in silicate 40. (Silicate 40 itself is about 4 mmol: 5-mer)]) of silicate 40 (manufactured by TAMA CHEMICALS CO., LTD.), 0.97 g (54 mmol) of water, 0.12 g (2 mmol) of acetic acid were added to a 50 mL flask, and after warming to 40° C., stirred for 1 hour. Thereafter, the temperature was increased to 70° C., and stirred for 2 hours. No insoluble matter occurred during agitation and the reaction solution was in a solution state. After stirring, a PGMEA solvent was added, and water, acetic acid, and by-produced ethanol and a part of PGMEA were distilled off using a rotary evaporator under reduced pressure at 60° C., and filtered under reduced pressure to obtain 81 g of a polysiloxane compound solution (composition) having a solid concentration of 10% by mass.

### Comparative Example 2

3.66 g (9 mmol) of the synthesized HHFIPTESB, 3.13 g (21 mmol [SiO₂ conversion contained in the silicate 40. (Silicate 40 itself about 4.2 mmol: as 5-mer)]) of silicate 40 (average 5-mer, TAMA CHEMICALS CO., LTD.), 0.7 g (39 mmol) of water, 0.09 g (1.5 mmol) of acetate was added to the flask of 50 mL, heated to 40° C., and after stirring for 4 hours, precipitation was generated in the middle of stirring. After filtration under reduced pressure, a PGMEA solvent was added to the obtained filtrate, and water, acetic acid, and by-produced ethanol and a part of PGMEA were distilled off using a rotary evaporator under reduced pressure at 60° C., and filtered again under reduced pressure to obtain 40 g of a polysiloxane compound solution (composition) having a solid concentration of 10% by mass.

### Comparative Example 3

4.06 g (10 mmol) of synthesized HHFIPTESB, 4.47 g (30 mmol [SiO₂ conversion contained in the silicate 40. (Silicate 40 itself is about 6 mmol: as a 5-mer)]) of silicate 40 (average 5-mer, manufactured by TAMA CHEMICALS CO., LTD.), 0.9 g (51 mmol) of water, 0.12 g (2 mmol) of acetic acid were added to the 50 mL flask, and instead of stirring at 40° C. for 4 hours, the mixture was stirred at 40° C. for 1 hour, and then the temperature was raised to 70° C., and stirred for 2 hours, whereby a precipitation was generated in the middle of stirring. After filtration under reduced pressure, a PGMEA solvent was added to the obtained filtrate, and water, acetic acid, and by-produced ethanol and a part of PGMEA were distilled off using a rotary evaporator under reduced pressure at 60° C., and filtered again under reduced pressure to obtain 50 g of a polysiloxane compound solution (composition) having a solid concentration of 10% by mass.

Details of the structure of the composition precursor (solution) and the composition described above and evaluation results are shown in table 1 and table 2.

TABLE 1

| | | | | | | | | pH of |
|---|---|---|---|---|---|---|---|---|
| | | | | | | | | composition |
| | Composition precursor | | | | | | | precursor |
| | R¹ | Mw | b | m | t | OR³ | s | solution |
| Example 1 | 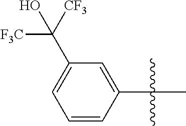 [SMILES: *c1cccc(C(O)(C(F)(F)F)C(F)(F)F)c1] | 607 | 1.0 | 0.0 | 0.2 | OEt OH | 2 0.8 total 2.8 | 2 |
| Example 2 | 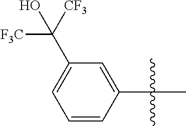 [SMILES: *c1cccc(C(O)(C(F)(F)F)C(F)(F)F)c1] | 607 | 1.0 | 0.0 | 0.2 | OEt OH | 2 0.8 total 2.8 | 2 |
| Example 3 | 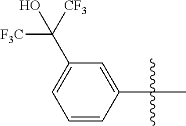 [SMILES: *c1cccc(C(O)(C(F)(F)F)C(F)(F)F)c1] | 632 | 1.0 | 0.0 | 0.5 | OEt OH | 0.4 2.1 total 2.5 | 3 |
| Example 4 | 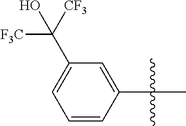 [SMILES: *c1cccc(C(O)(C(F)(F)F)C(F)(F)F)c1] | 589 | 1.0 | 0.0 | 0.4 | OEt OH | 0.1 2.5 total 2.6 | 2 |
| Comparative example 1 | 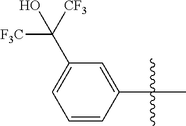 [SMILES: *c1cccc(C(O)(C(F)(F)F)C(F)(F)F)c1] | 406 | 1.0 | 0.0 | 0 | OEt OH | 3 0 total 3 | — |
| Comparative example 2 | 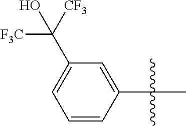 [SMILES: *c1cccc(C(O)(C(F)(F)F)C(F)(F)F)c1] | 406 | 1.0 | 0.0 | 0 | OEt OH | 3 0 total 3 | — |
| Comparative example 3 | 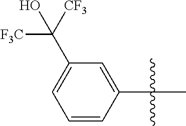 [SMILES: *c1cccc(C(O)(C(F)(F)F)C(F)(F)F)c1] | 405 | 1.0 | 0.0 | 0 | OEt OH | 3 0 total 3 | — |

TABLE 2

| | Polysiloxane compound (A) | | | | | | | | | | |
|---|---|---|---|---|---|---|---|---|---|---|---|
| | Individuals | | | | | | | | | | |
| | detected | | | | | | | | | | |
| | during the | | | | | | | | composition | | |
| | manufacturing | Q/(Q + T) | | | | | | | | | Viscosity |
| | process | ratio | b | m | l | n | p | q | pH | Mw | (mPa · s) |
| Example 1 | No | 0.71 | 1.0 | 0.0 | 1.9 | 1.1 | 1.4 | 2.6 | 4 | 2540 | 2.2 |
| Example 2 | No | 0.69 | 1.0 | 0.0 | 1.2 | 1.8 | 1.1 | 2.9 | 4 | 15200 | 2.4 |
| Example 3 | No | 0.78 | 1.0 | 0.0 | 0.5 | 2.5 | 0.8 | 3.2 | 4 | 3000 | 2.2 |
| Example 4 | No | 0.86 | 1.0 | 0.0 | 1.0 | 2.0 | 0.8 | 3.2 | 4 | 2990 | 2.2 |
| Comparative | No | 0.51 | 1.0 | 0.0 | 1.8 | 1.2 | 1.5 | 2.5 | 4 | 1860 | 2.1 |
| example 1 | | | | | | | | | | | |
| Comparative | Yes | 0.56 | 1.0 | 0.0 | 2.0 | 1.0 | 1.3 | 2.7 | 4 | 2410 | 2.1 |
| example 2 | | Value of | | | | | | | | | |
| | | Polysiloxane | | | | | | | | | |
| | | compounds in | | | | | | | | | |
| | | filtrate after | | | | | | | | | |
| | | decompression | | | | | | | | | |
| | | filtration | | | | | | | | | |
| Comparative | Yes | 0.58 | 1.0 | 0.0 | 1.8 | 1.2 | 1.2 | 2.8 | 4 | 2250 | 2.2 |
| example 3 | | Value of | | | | | | | | | |
| | | Polysiloxane | | | | | | | | | |
| | | compounds in | | | | | | | | | |
| | | filtrate after | | | | | | | | | |
| | | decompression | | | | | | | | | |
| | | filtration | | | | | | | | | |

### [Etching Rate and Evaluation of Etching Selectivity]

The compositions according to the examples and comparative examples obtained above were filtered by a filter having a pore size of 0.22 μm, spin-coated on a silicon wafer having a diameter of 4 inches and a thickness of 525 μm manufactured by SUMGO CORPORATION at a rotational speed of 250 rpm, and then the silicon wafer was baked on a hot plate at 200° C. for 3 minutes. In this manner, a cured product film of the above composition having a thickness of 0.4 to 0.6 μm was formed on a silicon wafer.

The obtained cured film on the silicon wafer was dry-etched with fluorine-based gas (CF₄ and CHF₃) and oxygen-based gas (CO₂ or O₂), and the etching rate for each gas was measured to calculate the etching selectivity. The etching conditions (1) to (3) are shown below (hereinafter, the etching rate may be simply referred to as a rate, and the etching condition may be simply referred to as a condition).

[Condition (1)] CF₄ and CHF₃ used as fluorine-based gas

CF₄ flow rate: 150 sccm

CHF₃ flow rate: 50 sccm

Ar flow rate: 100 sccm

chamber pressure: 10 Pa

applied power: 400 W

temperature: 15° C.

[Condition (2)] CO₂ used as oxygen-based gas

CO₂ flow rate: 300 sccm

Ar flow rate: 100 sccm

N₂ flow rate: 100 sccm

chamber pressure: 2 Pa

applied power: 400 W

temperature: 15° C.

[Condition (3)] O₂ used as oxygen-based gas

O₂ flow rate: 400 sccm

Ar flow rate: 100 sccm

chamber pressure: 2 Pa

applied power: 400 W

temperature: 15° C.

Measurements of the etching rate in the etching condition (1) to (3) and the etching rate ratio obtained from the measurements are shown in Table 3. Etching rate ratio A is a measurement obtained by dividing the measurement of the speed according to condition (1) by the measurement of the speed according to condition (2), the etching rate ratio B is a value obtained by dividing the measurement of the speed according to condition (1) by the measurement of the speed according to condition (3).

TABLE 3

| | Measured etching rate | | | | |
|---|---|---|---|---|---|
| | (nm/min) | | | Etching selectivity | |
| | condition | condition | condition | Etching | Etching |
| | (1) | (2) | (3) | rate | rate |
| | CF₄ + CHF₃ | CO₂ | O₂ | ratio A | ratio B |
| Example 1 | 93 | 1.0 | 1.5 | 93 | 62 |
| Example 2 | 80 | 1.0 | 1.4 | 80 | 57 |
| Example 3 | 76 | 0.6 | 1.3 | 127 | 58 |
| Example 4 | 73 | 0.6 | 1.1 | 121 | 66 |
| Comparative | 91 | 2.0 | 5.0 | 46 | 18 |
| example 1 | | | | | |

As shown in table 3, the cured film obtained using the composition of the example in which the Q/(Q+T) ratio is 0.6 or more is superior to the cured film obtained using the composition of the comparative example in which the Q/(Q+T) ratio is less than 0.6 in O₂ plasma etching resistance (O₂ etching rate of Condition (3) is smaller). As a result, the cured film according to the example was superior in etching selectivity of the fluorine-based gas and the oxygen-based gas as compared with the cured film according to the comparative example (both of the rate ratios (A) and (B) of etching selectivity are larger.)

In example 1, when the pH is changed, the results of investigation on the storage stability are shown in table 4, example 1 has a pH of 4, example 1-1 has a pH of 2, example 1-2 has a pH of 3, example 1-3 has a pH of 6, and example 1-4 has a pH of 9.

TABLE 4

Storage stability test

| | | Before | After |
|---|---|---|---|
| | pH of | Storage | Storage |
| | composition | Mw | Mw |
| Example 1 | 4 | 2540 | 2520 |
| Example 1-1 | 2 | 2540 | 3110 |
| Example 1-2 | 3 | 2540 | 2490 |
| Example 1-3 | 6 | 2540 | 9400 |
| Example 1-4 | 9 | 2540 | 26200 |

As shown in table 4, the storage stability of the composition was the most excellent in example 1, example 1-2, in which the pH at 25° C. was more than 2 and 5 or less, and then in the order of example 1-1, in which the pH was 2, example 1-3, in which the pH was 6, and example 1-4, in which the pH was 9. Note that the compositions of examples 1-1 and 1-2 are obtained by adding maleic acid to the compositions obtained in example 1 so that the pH is 2 and 3, respectively. The compositions of examples 1-3 and 1-4 are obtained by adding triethylamine to the compositions obtained in example 1 so that the pH is 6 and 9, respectively.

### Advantageous Effects of Invention

According to one embodiment of the present invention, a composition with a high content of Q units (specifically, the ratio of Q unit/(Q unit+T unit) in the total Si structural units is 0.60 or more.)

What is claimed is:

1. A composition comprising:
a polysiloxane compound (A) containing a structural unit represented by formula (1) and a structural unit represented by formula (2), a siloxane structural unit ratio represented by
Q unit/(Q unit+T unit)
in all Si structural units being 0.60 or more and less than 1.00;
and the solvent (B),
[(R¹)_{b}(R²)ₘ(OR³)ₗSiO_{n/2}] (1)
wherein in the formula, R¹ is a group represented by following formula, 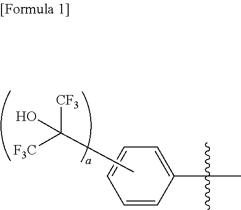
a is a number of 1 to 5, the wavy line indicates that the intersecting line segment is a bond,
wherein R² is each independently a hydrogen atom, an alkyl group having 1 or more and 3 or less carbon atoms, a phenyl group, or a fluoroalkyl group having 1 or more and 3 or less carbon atoms,
wherein R³ is each independently a hydrogen atom, or an alkyl group having 1 or more and 3 or less carbon atoms,
b is a number of 1 to 3, m is a number of 0 to 2, l is a number of 0 or more and less than 3, n is a number of more than 0 and 3 or less, and b+m+l+n=4, and
[(R⁴)ₚSiO_{q/2}] (2)
wherein in the formula, R⁴ is independently an alkoxy group having 1 or more and 3 or less carbon atoms, a hydroxyl group, or a halogen group, p is a number of 0 or more and less than 4, q is a number of more than 0 and 4 or less, and p+q=4.

2. The composition according to claim 1, wherein a is 1 or 2.

3. The composition according to claim 1, wherein R¹ is one of following, 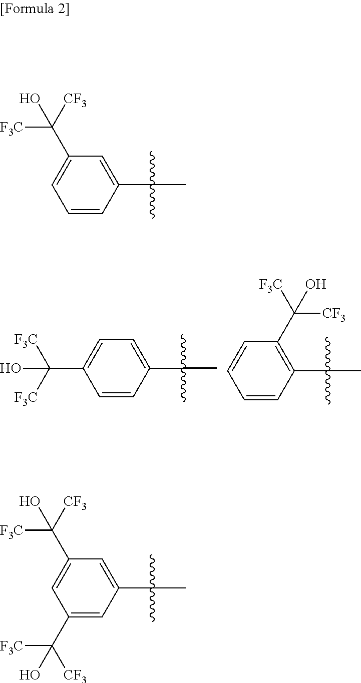
wherein the wavy line indicates that the intersecting line segment is a bond.

4. The composition according to claim 1, wherein b is 1.

5. The composition according to claim 1, wherein n is 0.5 to 3.

6. The composition according to claim 1, wherein the pH at 25° C. is 1 or more and less than 6.

7. The composition according to claim 1, wherein a viscosity at 25° C. is 0.5 mPa·s or more 30 mPa·s or less.

8. The composition according to claim 1, wherein the solvent (B) includes at least one selected from a group consisting of an ester-based solvent, an ether-based solvent, an alcohol-based solvent, a ketone-based solvent, and an amide-based solvent.

9. The composition according to claim 1, wherein an under layer film of a photoresist is formed of the composition.

10. The composition according to claim 1, wherein an etching rate ratio A obtained by dividing an etching rate under following condition (1) with respect to a film to be etched formed of the composition by an etching rate under following condition (2) is 50 or more.
[Condition (1)] CF₄ and CHF₃ used as the fluorine-based gas
CF₄ flow rate: 150 sccm
CHF₃ flow rate: 50 sccm
Ar flow rate: 100 sccm
chamber pressure: 10 Pa
applied electric power: 400 W
temperature: 15° C.
[Condition (2)] CO₂ used as the oxygen-based gas
CO₂ flow rate: 300 sccm
Ar flow rate: 100 sccm
N₂ flow rate: 100 sccm
chamber pressure: 2 Pa
applied electric power: 400 W
temperature: 15° C.

11. The composition according to claim 1, wherein an etching rate ratio B obtained by dividing an etching rate under following condition (1) with respect to a film to be etched formed of the composition by an etching rate under following condition (3) is 20 or more.
[Condition (1)] CF₄ and CHF₃ used as the fluorine-based gas
CF₄ flow rate: 150 sccm
CHF₃ flow rate: 50 sccm
Ar flow rate: 100 sccm
chamber pressure: 10 Pa
applied electric power: 400 W
temperature: 15° C.
[Condition (3)] O₂ used as the oxygen-based gas
O₂ flow rate: 400 sccm
Ar flow rate: 100 sccm
chamber pressure: 2 Pa
applied electric power: 400 W
temperature: 15° C.

12. A composition precursor solution comprising:
a composition precursor,
wherein the composition precursor is copolymerizable with at least one selected from a group consisting of chlorosilane, alkoxysilane, and silicate oligomers that give the structural units represented by following formula (2) to provide the composition according to claim 1,
the composition precursor contains the structural unit represented by following formula (3), and
the composition precursor solution has a pH of 1 or more and 7 or less at 25° C.,
[(R⁴)ₚSiO_{q/2}] (2)
wherein in the formula, R⁴ is independently an alkoxy group having 1 or more and 3 or less carbon atoms, hydroxyl group, or halogen group, p is a number of 0 or more and less than 4, q is a number of more than 0 and 4 or less, and p+q=4.]
[(R¹)_{b}(R²)ₘ(OR³)ₛSiO_{t/2}) (3)
wherein in the formula, R¹ is a group represented by following formula, 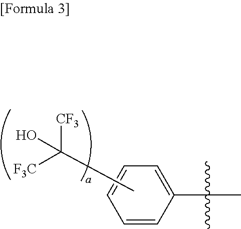
a is a number of 1 to 5, the wavy line indicates that intersecting line segment is a bond,
wherein R² is each independently a hydrogen atom, an alkyl group having 1 or more and 3 or less carbon atoms, a phenyl group, or a fluoroalkyl group having 1 or more and 3 or less carbon atoms,
wherein R³ is each independently a hydrogen atom, or an alkyl group having 1 or more and 3 or less carbon atoms, b is a number of 1 to 3, m is a number of 0 to 2, s is a number of 0 or more and less than 3, t is a number of more than 0 and 3 or less, and b+m+s+t=4.

13. The composition precursor solution according to claim 12, wherein a weight average molecular weight of the composition precursor is 300 to 3000.

14. The composition precursor solution according to claim 12, wherein a is 1 or 2.

15. The composition precursor solution according to claim 12, wherein R¹ is one of following, 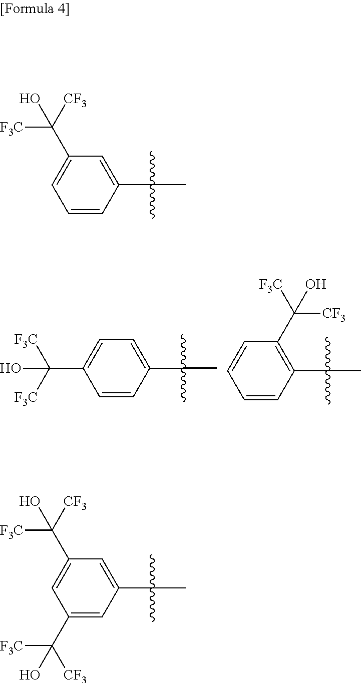
wherein the wavy line indicates that intersecting line segment is a bond.

16. The composition precursor solution according to claim 12, wherein b is 1.

17. A production method for a composition comprising:
mixing and copolymerizing the composition precursor solution according to claim 12 and at least one selected from a group consisting of chlorosilane, alkoxysilane, and silicate oligomers which give a structural unit represented by following formula (2),
[(R⁴)ₚSiO_{q/2}] (2)
wherein in the formula, R⁴ is independently an alkoxy group having 1 or more and 3 or less carbon atoms, a hydroxyl group, or a halogen group, p is a number of 0 or more and less than 4, q is a number of more than 0 and 4 or less, and p+q=4.

18. A substrate with multilayer film comprising:
a substrate;
an organic layer on the substrate; and
an under layer film of a photoresist being a cured product of the composition according to claim 1 on the organic layer, and a resist layer on the under layer film.

19. A production method for a patterned substrate comprising:
a first step of obtaining a first pattern by exposing a resist layer with a high energy ray through a photomask to the substrate with the multilayer film according to claim 18 and developing the resist layer with a developer,
a second step of dry etching an under layer film through the first pattern of the resist layer to obtain a second pattern in the under layer film,
a third step of dry etching an organic layer through the second pattern of the under layer film to obtain a third pattern in the organic layer, and
a fourth step of dry etching the substrate through the third pattern of the organic layer to obtain a fourth pattern in the substrate.

20. The production method for a patterned substrate according to claim 19, wherein
in the second step, dry etching of the under layer film is performed with a fluorine-based gas,
in the third step, dry etching of the organic layer is performed with an oxygen-based gas, and
in the fourth step, dry etching of the substrate is performed with a fluorine-based gas or a chlorine-based gas.

21. The production method for a patterned substrate according to claim 19, wherein
the high energy ray is an ultraviolet ray having a wavelength of 1 nm or more and 400 nm or less.

22. The production method for a patterned substrate according to claim 19, wherein in the under layer film, the etching rate ratio A obtained by dividing the etching rate under following condition (1) by the etching rate under following condition (2) is 50 or more;
[Condition (1)] CF₄ and CHF₃ used as the fluorine-based gas
CF₄ flow rate: 150 sccm
CHF₃ flow rate: 50 sccm
Ar flow rate: 100 sccm
chamber pressure: 10 Pa
applied electric power: 400 W
temperature: 15° C.
[Condition (2)] CO₂ used as the oxygen-based gas
CO₂ flow rate: 300 sccm
Ar flow rate: 100 sccm
N₂ flow rate: 100 sccm
chamber pressure: 2 Pa
applied electric power: 400 W
temperature: 15° C.

23. The production method for a patterned substrate according to claim 19, wherein in the under layer film, the etching rate ratio B obtained by dividing the etching rate under following condition (1) by the etching rate under following condition (3) is 20 or more:
[Condition (1)] CF₄ and CHF₃ used as the fluorine-based gas
CF₄ flow rate: 150 sccm
CHF₃ flow rate: 50 sccm
Ar flow rate: 100 sccm
chamber pressure: 10 Pa
applied electric power: 400 W
temperature: 15° C.
[Condition (3)] O₂ used as the oxygen-based gas
O₂ flow rate: 400 sccm
Ar flow rate: 100 sccm
chamber pressure: 2 Pa
applied electric power: 400 W
temperature: 15° C.
